(19) United States
(12) Patent Application Publication
(10) Pub. No.: US 2024/0295813 A1
(43) Pub. Date: Sep. 5, 2024

(54) PHOTOSENSITIVE COMPOSITION

(71) Applicant: FUJIFILM Corporation, Tokyo (JP)

(72) Inventors: Takahiro OKAWARA, Haibara-gun (JP); Yuki NARA, Haibara-gun (JP); Shoichi NAKAMURA, Haibara-gun (JP); Mitsuji YOSHIBAYASHI, Haibara-gun (JP)

(73) Assignee: FUJIFILM Corporation, Tokyo (JP)

(21) Appl. No.: 18/617,226

(22) Filed: Mar. 26, 2024

Related U.S. Application Data
(63) Continuation of application No. 16/924,293, filed on Jul. 9, 2020.
Application No. 16/924,293 is a continuation of application No. PCT/JP2019/005035, filed on Feb. 13, 2019.

(30) Foreign Application Priority Data
Feb. 16, 2018 (JP) 2018-026163

(51) Int. Cl. G03F 7/031; G02B 1/04; G02B 5/20; G03F 7/075; H01L 27/146

(52) U.S. Cl. CPC G03F 7/031; G02B 1/04; G02B 5/208; G03F 7/075; H01L 27/14621

(57) ABSTRACT

A photosensitive composition for exposure to light having a wavelength of 300 nm or shorter, the photosensitive composition including: a coloring material; and a polymerizable monomer, in which the total content of the polymerizable monomer and a photopolymerization initiator is 15 mass % or lower with respect to the total solids content of the photosensitive composition.

### CROSS-REFERENCE TO RELATED APPLICATIONS

This application is a Continuation of application Ser. No. 16/924,293 filed Jul. 9, 2020, which is a Continuation of PCT International Application No. PCT/JP2019/005035 filed Feb. 13, 2019, which claims priority under 35 U.S.C § 119(a) to Japanese Patent Application No. 2018-026163 filed Feb. 16, 2018. Each of the above application(s) is hereby expressly incorporated by reference, in its entirety, into the present application.

### BACKGROUND OF THE INVENTION

### Field of the Invention

The present invention relates to a photosensitive composition including a coloring material. More specifically, the present invention relates to a photosensitive composition used for a solid-state imaging element, a color filter, or the like.

### Description of the Related Art

In a video camera, a digital still camera, a mobile phone with a camera function, or the like, a solid-state imaging element such as a charge coupled device (CCD) or a complementary metal-oxide semiconductor (CMOS) is used. In addition, in a solid-state imaging element, a film including a coloring material such as a color filter is used. The film including a coloring material such as a color filter is formed, for example, using a photosensitive composition including a coloring material, a polymerizable monomer, and a photopolymerization initiator (refer to JP2012-532334A and JP2010-097172A).

### SUMMARY OF THE INVENTION

In a film including a coloring material, in a case where the curing of the film is insufficient, the coloring material flows out from the film, which may cause color transfer to another film. Therefore, in order to form a film including a coloring material, it is necessary to form a film that is sufficiently cured. In order to improve curing properties of a photosensitive composition, in the related art, a photosensitive composition including a relatively large amount of a polymerizable monomer and a relatively large amount of a photopolymerization initiator is used. For example, in Example 6 of JP2012-532334A, a photosensitive composition includes 23.69 mass % of a polymerizable monomer and 1 mass % of a photopolymerization initiator with respect to the total solid content of the photosensitive composition. In addition, in Example 1 of JP2010-097172A, a photosensitive composition includes 20.5 mass % of polymerizable monomers in total and 5.8 mass % of a photopolymerization initiator with respect to the total solid content of the photosensitive composition.

On the other hand, recently, a reduction in the thickness of a film including a coloring material has been considered. For example, in order to reduce the thickness of a film while maintaining desired spectral characteristics, it is desirable to increase a coloring material concentration in the film. However, a photosensitive composition of the related art includes a relatively large amount of a polymerizable monomer and a relatively large amount of a photopolymerization initiator as components other than a coloring material. Therefore, it is difficult to further increase the content of a coloring material or the like while maintaining sufficient curing properties.

Accordingly, an object of the present invention is to provide a photosensitive composition having excellent curing properties even in a case where the contents of a polymerizable monomer and a photopolymerization initiator are low.

The present inventors conducted a thorough investigation on a photosensitive composition and found that, by irradiating and exposing a photosensitive composition with and to light having a wavelength of 300 nm or shorter, a film that has excellent curing properties and is sufficiently cured can be formed even in a case where the contents of a polymerizable monomer and a photopolymerization initiator are low with respect to the total solid content of the photosensitive composition, thereby completing the present invention. Accordingly, the present invention provides the following.

<1> A photosensitive composition for exposure to light having a wavelength of 300 nm or shorter, the photosensitive composition comprising:
a coloring material; and
a polymerizable monomer,
wherein a total content of the polymerizable monomer and a photopolymerization initiator is 15 mass % or lower with respect to a total solid content of the photosensitive composition.

<2> The photosensitive composition according to <1>,
in which a content of the polymerizable monomer is 50 mass % or higher with respect to the total content of the polymerizable monomer and the photopolymerization initiator.

<3> The photosensitive composition according to <1>,
in which a content of the polymerizable monomer is 70 mass % to 90 mass % with respect to the total content of the polymerizable monomer and the photopolymerization initiator.

<4> The photosensitive composition according to any one of <1> to <3>,
in which a content of the polymerizable monomer is 13 mass % or lower with respect to the total solid content of the photosensitive composition.

<5> The photosensitive composition according to any one of <1> to <3>,
wherein a content of the photopolymerization initiator is 5 mass % or lower with respect to the total solid content of the photosensitive composition.

<6> The photosensitive composition according to any one of <1> to <5>,
in which a content of the photopolymerization initiator is 5 parts by mass or less with respect to 100 parts by mass of the coloring material.

<7> The photosensitive composition according to any one of <1> to <5>,
in which a content of the photopolymerization initiator is 1 part by mass to 5 parts by mass with respect to 100 parts by mass of the coloring material.

<8> The photosensitive composition according to any one of <1> to <7>,
in which a content of the coloring material is 50 mass % or higher with respect to the total solid content of the photosensitive composition.

<9> The photosensitive composition according to any one of <1> to <8>,
in which the polymerizable monomer is a polymerizable monomer having two or more functional groups.

<10> The photosensitive composition according to any one of <1> to <9>,
in which the polymerizable monomer is a polymerizable monomer having a fluorene skeleton.

<11> The photosensitive composition according to any one of <1> to <10>,
in which the coloring material includes a chromatic colorant.

<12> The photosensitive composition according to any one of <1> to <11>, further comprising:
a silane coupling agent.

<13> The photosensitive composition according to any one of <1> to <12>, which is a photosensitive composition for pulse exposure.

<14> The photosensitive composition according to any one of <1> to <13>, which is a photosensitive composition for a solid-state imaging element.

<15> The photosensitive composition according to any one of <1> to <14>, which is a photosensitive composition for a color filter.

According to the present invention, a photosensitive composition having excellent curing properties can be provided.

Hereinafter, the details of the present invention will be described.

In this specification, numerical ranges represented by “to” include numerical values before and after “to” as lower limit values and upper limit values.

In this specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In this specification, “(meth)allyl group” denotes either or both of allyl and methallyl, “(meth)acrylate” denotes either or both of acrylate or methacrylate, “(meth)acryl” denotes either or both of acryl and methacryl, and “(meth)acryloyl” denotes either or both of acryloyl and methacryloyl.

In this specification, a weight-average molecular weight and a number-average molecular weight denote values in terms of polystyrene measured by gel permeation chromatography (GPC).

In this specification, infrared light denotes light in a wavelength range of 700 to 2500 nm.

In this specification, a total solid content denotes the total mass of all the components of the composition excluding a solvent.

In this specification, the term “step” denotes not only an individual step but also a step which is not clearly distinguishable from another step as long as an effect expected from the step can be achieved.

### <Photosensitive Composition>

A photosensitive composition according to an embodiment of the present invention for exposure to light having a wavelength of 300 nm or shorter, the photosensitive composition comprises:
a coloring material; and
a polymerizable monomer,
in which a total content of the polymerizable monomer and a photopolymerization initiator is 15 mass % or lower with respect to a total solid content of the photosensitive composition.

By exposing the photosensitive composition according to the embodiment of the present invention to light having a wavelength of 300 nm or shorter, curing properties are excellent even in a case where the total content of the polymerizable monomer and the photopolymerization initiator are low with respect to the total solid content of the photosensitive composition. The reason why this effect is obtained is presumed to be as follows. It is presumed that, by irradiating and exposing the photosensitive composition to and with light having a wavelength of 300 nm or shorter such as a KrF ray, an active species such as a radical is generated even from the component such as the polymerizable monomer included in the photosensitive composition such that the polymerizable monomer can be efficiently cured. As a result, it is presumed that curing properties are excellent even in a case where the total content of the polymerizable monomer and the photopolymerization initiator are low with respect to the total solid content of the photosensitive composition. In addition, in the photosensitive composition according to the embodiment of the present invention, the total content of the polymerizable monomer and the photopolymerization initiator can be reduced, and thus the degree of freedom for the formula design is high. For example, by increasing the content of the coloring material with respect to the total solid content of the photosensitive composition, a film having a high coloring material concentration can be formed, and thus the thickness of the film can be reduced.

In the photosensitive composition according to the embodiment of the present invention, the total content of the polymerizable monomer and the photopolymerization initiator is preferably 15 mass % or lower, more preferably 12 mass % or lower, still more preferably 10 mass % or lower, and still more preferably 8 mass % or lower with respect to the total solid content of the photosensitive composition. In order to obtain sufficient curing properties, the lower limit is preferably 1 mass % or higher, more preferably 2 mass % or higher, still more preferably 3 mass % or higher, and still more preferably 4 mass % or higher.

The photosensitive composition according to the embodiment of the present invention is a photosensitive composition for exposure to light having a wavelength of 300 nm or shorter. The light used for the exposure is not particularly limited as long as it is light having a wavelength of 300 nm or shorter, and is preferably light having a wavelength of 270 nm or shorter and more preferably light having a wavelength of 250 nm or shorter. In addition, the above-described light is preferably light having a wavelength of 180 nm or longer. Specific examples of the light include a KrF ray (wavelength: 248 nm) and an ArF ray (wavelength: 193 nm). From the viewpoint of easily obtaining higher curing properties, a KrF ray (wavelength: 248 nm) is preferable.

In addition, it is also preferable that the photosensitive composition according to the embodiment of the present invention is a photosensitive composition for pulse exposure. That is, it is preferable that the photosensitive composition according to the embodiment of the present invention is used after being irradiated with and exposed (pulse exposure) to pulses of light having a wavelength of 300 nm or shorter. In this aspect, it is presumed that an active species such as a radical is more effectively generated even from the polymerizable monomer during exposure of the photosensitive composition such that the polymerizable monomer can be more efficiently cured. As a result, curing properties are excellent even in a case where the total content of the polymerizable monomer and the photopolymerization initiator are lower with respect to the total solid content of the photosensitive composition. Accordingly, the total content of the polymerizable monomer and the photopolymerization initiator with respect to the total solid content of the photosensitive composition can be further reduced while maintaining excellent curing properties. The pulse exposure refers to an exposure method in which light irradiation and rest are repeated in a cycle of a short period of time (for example, a level of milliseconds).

The photosensitive composition according to the embodiment of the present invention is preferably used as a composition for forming a colored pixel, a black pixel, a light blocking film, a pixel of an infrared transmitting filter layer, or the like. Examples of the colored pixel include a pixel of a color selected from red, blue, green, cyan, magenta, or yellow. Examples of the pixel of the infrared transmitting filter layer include a pixel of a filter layer satisfying spectral characteristics in which a maximum value of a transmittance in a wavelength range of 400 to 640 nm is 20% or lower (preferably 15% or lower and more preferably 10% or lower) and a minimum value of a transmittance in a wavelength range of 1100 to 1300 nm is 70% or higher (preferably 75% or higher and more preferably 80% or higher). In addition, it is also preferable that the pixel of the infrared transmitting filter layer is a pixel of a filter layer satisfying any one of the following spectral characteristics (1) to (4).

(1): a pixel of a filter layer in which a maximum value of a transmittance in a wavelength range of 400 to 640 nm is 20% or lower (preferably 15% or lower and more preferably 10% or lower) and a minimum value of a transmittance in a wavelength range of 800 to 1300 nm is 70% or higher (preferably 75% or higher and more preferably 80% or higher).

(2): a pixel of a filter layer in which a maximum value of a transmittance in a wavelength range of 400 to 750 nm is 20% or lower (preferably 15% or lower and more preferably 10% or lower) and a minimum value of a transmittance in a wavelength range of 900 to 1300 nm is 70% or higher (preferably 75% or higher and more preferably 80% or higher).

(3): a pixel of a filter layer in which a maximum value of a transmittance in a wavelength range of 400 to 830 nm is 20% or lower (preferably 15% or lower and more preferably 10% or lower) and a minimum value of a transmittance in a wavelength range of 1000 to 1300 nm is 70% or higher (preferably 75% or higher and more preferably 80% or higher).

(4): a pixel of a filter layer in which a maximum value of a transmittance in a wavelength range of 400 to 950 nm is 20% or lower (preferably 15% or lower and more preferably 10% or lower) and a minimum value of a transmittance in a wavelength range of 1100 to 1300 nm is 70% or higher (preferably 75% or higher and more preferably 80% or higher).

In a case where the photosensitive composition according to the embodiment of the present invention is used as a composition for forming a pixel of an infrared transmitting filter layer, it is preferable that the photosensitive composition according to the embodiment of the present invention satisfies spectral characteristics in which a ratio Amin/Bmax of a minimum value Amin of an absorbance of the composition in a wavelength range of 400 to 640 nm to a maximum value Bmax of an absorbance of the composition in a wavelength range of 1100 to 1300 nm is 5 or higher. Amin/Bmax is more preferably 7.5 or higher, still more preferably 15 or higher, and still more preferably 30 or higher.

An absorbance Aλ at a wavelength λ is defined by the following Expression (1).

$$A λ = - log ( T λ / 100 ) \qquad ( 1 )$$

Aλ represents the absorbance at the wavelength λ, and TX represents a transmittance (%) at the wavelength λ.

In the present invention, a value of the absorbance may be a value measured in the form of a solution or a value of a film which is formed using the photosensitive composition. In a case where the absorbance is measured in the form of the film, it is preferable that the absorbance is measured using a film that is formed by applying the photosensitive composition to a glass substrate using a method such as spin coating such that the thickness of the dried film is a predetermined value, and drying the applied composition using a hot plate at 100° C. for 120 seconds.

In a case where the photosensitive composition according to the embodiment of the present invention is used as a composition for forming a pixel of an infrared transmitting filter layer, it is more preferable that the photosensitive composition according to the embodiment of the present invention satisfies any one of the following spectral characteristics (11) to (14).

(11): A ratio Amin1/Bmax1 of a minimum value Amin1 of an absorbance of the photosensitive composition in a wavelength range of 400 to 640 nm to a maximum value Bmax1 of an absorbance of the photosensitive composition in a wavelength range of 800 to 1300 nm is 5 or higher, preferably 7.5 or higher, more preferably 15 or higher, and still more preferably 30 or higher. In this aspect, a film that can block light in a wavelength range of 400 to 640 nm and allows transmission of light having a wavelength of 720 nm or longer can be formed.

(12): A ratio Amin2/Bmax2 of a minimum value Amin2 of an absorbance of the photosensitive composition in a wavelength range of 400 to 750 nm to a maximum value Bmax2 of an absorbance of the photosensitive composition in a wavelength range of 900 to 1300 nm is 5 or higher, preferably 7.5 or higher, more preferably 15 or higher, and still more preferably 30 or higher. In this aspect, a film that can block light in a wavelength range of 400 to 750 nm and allows transmission of light having a wavelength of 850 nm or longer can be formed.

(13): A ratio Amin3/Bmax3 of a minimum value Amin3 of an absorbance of the photosensitive composition in a wavelength range of 400 to 850 nm to a maximum value Bmax3 of an absorbance of the photosensitive composition in a wavelength range of 1000 to 1300 nm is 5 or higher, preferably 7.5 or higher, more preferably 15 or higher, and still more preferably 30 or higher. In this aspect, a film that can block light in a wavelength range of 400 to 850 nm and allows transmission of light having a wavelength of 940 nm or longer can be formed.

(14): A ratio Amin4/Bmax4 of a minimum value Amin4 of an absorbance of the photosensitive composition in a wavelength range of 400 to 950 nm to a maximum value Bmax4 of an absorbance of the photosensitive composition in a wavelength range of 1100 to 1300 nm is 5 or higher, preferably 7.5 or higher, more preferably 15 or higher, and still more preferably 30 or higher. In this aspect, a film that can block light in a wavelength range of 400 to 950 nm and allows transmission of light having a wavelength of 1040 nm or longer can be formed.

The photosensitive composition according to the embodiment of the present invention can be preferably used as a photosensitive composition for a solid-state imaging element. In addition, the photosensitive composition according to the embodiment of the present invention can be preferably used as a photosensitive composition for a color filter. Specifically, the photosensitive composition according to the embodiment of the present invention can be preferably used as a photosensitive composition for forming a pixel of a color filter, and can be more preferably used as a photosensitive composition for forming a pixel of a color filter used in a solid-state imaging element.

Hereinafter, each of the components used in the photosensitive composition according to the embodiment of the present invention will be described.

### <<Coloring Material>>

The photosensitive composition according to the embodiment of the present invention includes a coloring material. Examples of the coloring material include a chromatic colorant, a black colorant, and an infrared absorbing colorant. It is preferable that the coloring material used in the photosensitive composition according to the embodiment of the present invention includes at least a chromatic colorant.

### (Chromatic Colorant)

Examples of the chromatic colorant include a red colorant, a green colorant, a blue colorant, a yellow colorant, a violet colorant, and an orange colorant. As the chromatic colorant, a pigment or a dye may be used. It is preferable that the chromatic colorant is a pigment. An average particle size (r) of the pigment satisfies preferably 20 nm≤r≤300 nm, more preferably 25 nm≤r≤250 nm, and still more preferably 30 nm≤r≤200 nm. “Average particle size” described herein denotes the average particle size of secondary particles which are aggregates of primary particles of the pigment. In addition, regarding a particle size distribution of the secondary particles of the pigment (hereinafter, simply referred to as “particle size distribution”) which can be used, secondary particles having a particle size of “average particle size ±100 nm” account for preferably 70 mass % or higher and more preferably 80 mass % or higher in the pigment.

As the pigment, an organic pigment is preferable. Preferable examples of the organic pigment are as follows:
Color Index (C.I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214 (all of which are yellow pigments);
C.I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);
C.I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279 (all of which are red pigments); C.I. Pigment Green 7, 10, 36, 37, 58, 59, 62, and 63 (all of which are green pigments); C.I. Pigment Violet 1, 19, 23, 27, 32, 37, and 42 (all of which are violet pigments); and C.I. Pigment Blue 1, 2, 15, 15:1, 15:2, 15:3, 15:4, 15:6, 16, 22, 60, 64, 66, 79, and 80 (all of which are blue pigments).

Among these organic pigments, one kind may be used alone, or two or more kinds may be used in combination.

In addition, as the yellow pigment, a metal azo pigment including at least one anion selected from an azo compound represented by the following Formula (I) or an azo compound having a tautomeric structure of the azo compound represented by Formula (I), two or more metal ions, and a melamine compound can be used.

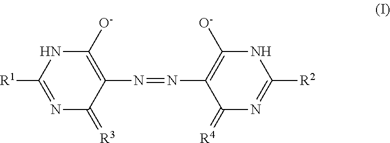

In the formula, R¹ and R² each independently represent —OH or —NR⁵R⁶, R³ and R⁴ each independently represent ═O or ═NR⁷, and R⁵ to R⁷ each independently represent a hydrogen atom or an alkyl group. The number of carbon atoms in the alkyl group represented by R⁵ to R⁷ is preferably 1 to 10, more preferably 1 to 6, and still more preferably 1 to 4. The alkyl group may be linear, branched, or cyclic and is preferably linear or branched and more preferably linear. The alkyl group may have a substituent. As the substituent, a halogen atom, a hydroxy group, an alkoxy group, a cyano group, or an amino group is preferable.

In Formula (I), it is preferable that R¹ and R² represent —OH. In addition, it is preferable that R³ and R⁴ represent ═O.

It is preferable that the melamine compound in the metal azo pigment is a compound represented by the following Formula (II).

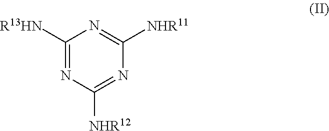

In the formula, R¹¹ to R¹³ each independently represent a hydrogen atom or an alkyl group. The number of carbon atoms in the alkyl group is preferably 1 to 10, more preferably 1 to 6, and still more preferably 1 to 4. The alkyl group may be linear, branched, or cyclic and is preferably linear or branched and more preferably linear. The alkyl group may have a substituent. As the substituent, a hydroxy group is preferable. It is preferable that at least one of R¹¹, . . . , or R¹³ represents a hydrogen atom, and it is more preferable that all of R¹¹ to R¹³ represent a hydrogen atom.

It is preferable that the above-described metal azo pigment is a metal azo pigment according to an aspect including at least one anion selected from an azo compound represented by Formula (I) or an azo compound having a tautomeric structure of the azo compound represented by Formula (I), metal ions including at least Zn²⁺ and Cu²⁺, and a melamine compound. In this aspect, the total content of Zn²⁺ and Cu²⁺ is preferably 95 to 100 mol %, more preferably 98 to 100 mol %, still more preferably 99.9 to 100 mol %, and still more preferably 100 mol % with respect to 1 mol of all the metal ions of the metal azo pigment. In addition, a molar ratio Zn²⁺:Cu²⁺ of Zn²⁺ to Cu²⁺ in the metal azo pigment is preferably 199:1 to 1:15, more preferably 19:1 to 1:1, and still more preferably 9:1 to 2:1. In addition, in this aspect, the metal azo pigment may further include a divalent or trivalent metal ion (hereinafter, also referred to as “metal ion Mel”) in addition to Zn²⁺ and Cu²⁺. Examples of the metal ion Mel include Ni²⁺, Al³⁺, Fe²⁺, Fe³⁺, Co²⁺, Co³⁺, La³⁺, Ce³⁺, Pr³⁺, Nd²⁺, Nd³⁺, Sm²⁺, Sm³⁺, Eu²⁺, Eu³⁺, Gd³⁺, Tb³⁺, Dy³⁺, Ho³⁺, Yb²⁺, Yb³⁺, Er³⁺, Tm³⁺, Mg²⁺, Ca²⁺, Sr²⁺, Mn²⁺, Y³⁺, Sc³⁺, Ti²⁺, Ti³⁺, Nb³⁺, Mo²⁺, Mo³⁺, V²⁺, V³⁺, Zr²⁺, Zr³⁺, Cd²⁺, Cr³⁺, Pb²⁺, and Ba²⁺. Among these, at least one selected from Al³⁺, Fe²⁺, Fe³⁺, Co²⁺, Co³⁺, La³⁺, Ce³⁺, Pr³⁺, Nd³⁺, Sm³⁺, Eu³⁺, Gd³⁺, Tb³⁺, Dy³⁺, Ho³⁺, Yb³⁺, Er³⁺, Tm³⁺, Mg²⁺, Ca²⁺, Sr²⁺, Mn²⁺, or Y³⁺ is preferable, at least one selected from Al³⁺, Fe²⁺, Fe³⁺, Co²⁺, Co³⁺, La³⁺, Ce³⁺, Pr³⁺, Nd³⁺, Sm³⁺, Tb³⁺, Ho³⁺, or Sr²⁺ is more preferable, and at least one selected from Al³⁺, Fe²⁺, Fe³⁺, Co²⁺, or Co³⁺ is still more preferable. The content of the metal ion Mel is preferably 5 mol % or lower, more preferably 2 mol % or lower, and still more preferably 0.1 mol % or lower with respect to 1 mol of all the metal ions of the metal azo pigment.

The details of the metal azo pigment can be found in paragraphs “0011” to “0062” and “0137” to “0276” of JP2017-171912A, paragraphs “0010” to “0062” and “0138” to “0295” of JP2017-171913A, paragraphs “0011” to “0062” and “0139” to “0190” of JP2017-171914A, and paragraphs “0010” to “0065” and “0142” to “0222” of JP2017-171915A, the contents of which are incorporated herein by reference.

In addition, as the red pigment, a compound having a structure in which an aromatic ring group into which a group having an oxygen atom, a sulfur atom, or a nitrogen atom bonded to an aromatic ring is introduced is bonded to a diketo pyrrolo pyrrole skeleton can also be used. This compound is preferably a compound represented by Formula (DPP1) and more preferably a compound represented by Formula (DPP2).

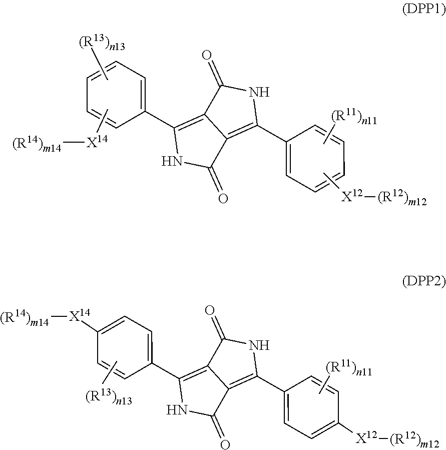

In the formula, R¹¹ and R¹³ each independently represent a substituent, R¹² and R¹⁴ each independently represent a hydrogen atom, an alkyl group, an aryl group, or a heteroaryl group, n11 and n13 each independently represent an integer of 0 to 4, X¹² and X¹⁴ each independently represent an oxygen atom, a sulfur atom, or a nitrogen atom, in a case where X¹² represents an oxygen atom or a sulfur atom, m12 represents 1, in a case where X¹² represents a nitrogen atom, m12 represents 2, in a case where X¹⁴ represents an oxygen atom or a sulfur atom, m14 represents 1, and in a case where X¹⁴ represents a nitrogen atom, m14 represents 2. Specific preferable example of the substituent represented by R¹¹ and R¹³ include an alkyl group, an aryl group, a halogen atom, an acyl group, an alkoxycarbonyl group, an aryloxycarbonyl group, a heteroaryloxycarbonyl group, an amido group, a cyano group, a nitro group, a trifluoromethyl group, a sulfoxide group, and a sulfo group.

In addition, as a green pigment, a halogenated zinc phthalocyanine pigment having 10 to 14 halogen atoms, 8 to 12 bromine atoms, and 2 to 5 chlorine atoms in one molecule on average can also be used. Specific examples of the green colorant include a compound described in WO2015/118720A.

In addition, as a blue pigment, an aluminum phthalocyanine compound having a phosphorus atom can also be used. Specific examples of the blue colorant include a compound described in paragraphs “0022” to “0030” of JP2012-247591A and paragraph “0047” of JP2011-157478A.

As the dye, well-known dyes can be used without any particular limitation. Examples of the dye include a dye such as a pyrazole azo dye, an anilino azo dye, a triarylmethane dye, an anthraquinone dye, an anthrapyridone dye, a benzylidene dye, an oxonol dye, a pyrazolotriazole azo dye, a pyridone azo dye, a cyanine dye, a phenothiazine dye, a pyrrolopyrazole azomethine dye, a xanthene dye, a phthalocyanine dye, a benzopyran dye, an indigo dye, and a pyrromethene dye. In addition, a polymer of the above-described dyes may be used. In addition, dyes described in JP2015-028144A and JP2015-034966A can also be used.

### (Black Colorant)

Examples of the black colorant include an inorganic black colorant such as carbon black, a metal oxynitride (for example, titanium black), or a metal nitride (for example, titanium nitride) and an organic black colorant such as a bisbenzofuranone compound, an azomethine compound, a perylene compound, or an azo compound. As the organic black colorant, a bisbenzofuranone compound or a perylene compound is preferable. Examples of the bisbenzofuranone compound include a compound described in JP2010-534726A, JP2012-515233A, and JP2012-515234A. For example, “Irgaphor Black” (manufactured by BASF SE) is available. Examples of the perylene compound include C.I. Pigment Black 31 and 32. Examples of the azomethine compound include compounds described in JP1989-170601A (JP-H1-170601A) and JP1990-034664A (JP-H2-034664A). For example, “CHROMOFINE BLACK A1103” (manufactured by Dainichiseika Color & Chemicals Mfg. Co., Ltd.) is available. It is preferable that the bisbenzofuranone compound is one of compounds represented by the following formulae or a mixture thereof.

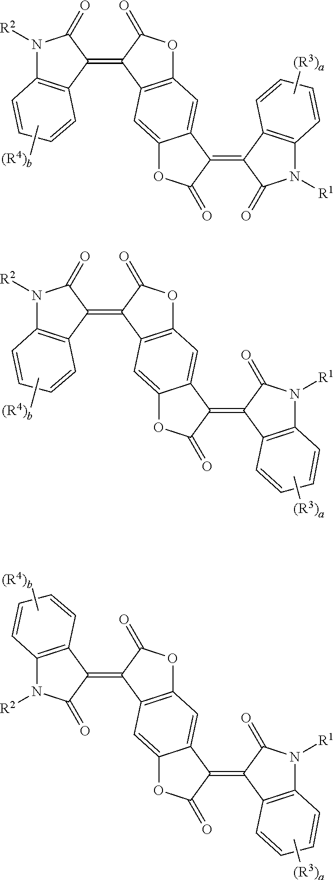

In the formulae, R¹ and R² each independently represent a hydrogen atom or a substituent, R³ and R⁴ each independently represent a substituent, a and b each independently represent an integer of 0 to 4, in a case where a is 2 or more, a plurality of R³'s may be the same as or different from each other, a plurality of R³'s may be bonded to each other to form a ring, in a case where b is 2 or more, a plurality of R⁴'s may be the same as or different from each other, and a plurality of R⁴'s may be bonded to each other to form a ring.

The substituent represented by R¹ to R⁴ is a halogen atom, a cyano group, a nitro group, an alkyl group, an alkenyl group, an alkynyl group, an aralkyl group, an aryl group, a heteroaryl group, —OR³⁰¹, —COR³⁰², —COOR³⁰³, —OCOR³⁰⁴, —NR³⁰⁵R³⁰⁶, —NHCOR³⁰⁷, —CONR³⁰⁸R³⁰⁹, —NHCONR³¹⁰R³¹¹, —NHCOOR³¹², —SR³¹³, —SO₂R³¹⁴, —SO₂OR³¹⁵, —NHSO₂R³¹⁶, or —SO₂NR³¹⁷R³¹⁸. R³⁰¹ to R³¹⁸ each independently represent a hydrogen atom, an alkyl group, an alkenyl group, an alkynyl group, an aryl group, or a heteroaryl group.

The details of the bisbenzofuranone compound can be found in paragraphs “0014” to “0037” of JP2010-534726A, the content of which is incorporated herein by reference.

### (Infrared Absorbing Colorant)

As the infrared absorbing colorant, a compound having a maximum absorption wavelength preferably in a wavelength range of 700 to 1300 nm and more preferably in a wavelength range of 700 to 1000 nm is preferable. The infrared absorbing colorant may be a pigment or a dye.

In the present invention, as the infrared absorbing colorant, a compound that includes a π-conjugated plane having a monocyclic or fused aromatic ring can be preferably used. The number of atoms constituting the π-conjugated plane included in the infrared absorbing colorant other than hydrogen is preferably 14 or more, more preferably 20 or more, still more preferably 25 or more, and still more preferably 30 or more. For example, the upper limit is preferably 80 or less and more preferably 50 or less. The number of monocyclic or fused aromatic rings in the π-conjugated plane included in the infrared absorbing colorant is preferably 2 or more, more preferably 3 or more, still more preferably 4 or more, and still more preferably 5 or more. The upper limit is preferably 100 or less, more preferably 50 or less, and still more preferably 30 or less. Examples of the aromatic ring include a benzene ring, a naphthalene ring, a pentalene ring, an indene ring, an azulene ring, a heptalene ring, an indacene ring, a perylene ring, a pentacene ring, a quaterrylene ring, an acenaphthene ring, a phenanthrene ring, an anthracene ring, a naphthacene ring, a chrysene ring, a triphenylene ring, a fluorene ring, a pyridine ring, a quinoline ring, an isoquinoline ring, an imidazole ring, a benzimidazole ring, a pyrazole ring, a thiazole ring, a benzothiazole ring, a triazole ring, a benzotriazole ring, an oxazole ring, a benzoxazole ring, an imidazoline ring, a pyrazine ring, a quinoxaline ring, a pyrimidine ring, a quinazoline ring, a pyridazine ring, a triazine ring, a pyrrole ring, an indole ring, an isoindole ring, a carbazole ring, and a fused ring including the above-described ring.

As the infrared absorbing colorant, at least one selected from a pyrrolopyrrole compound, a cyanine compound, a squarylium compound, a phthalocyanine compound, a naphthalocyanine compound, a quaterrylene compound, a merocyanine compound, a croconium compound, an oxonol compound, a diimmonium compound, a dithiol compound, a triarylmethane compound, a pyrromethene compound, an azomethine compound, an anthraquinone compound, or a dibenzofuranone compound is preferable, at least one selected from a pyrrolopyrrole compound, a cyanine compound, a squarylium compound, a phthalocyanine compound, a naphthalocyanine compound, or a diimmonium compound is more preferable, at least one selected from a pyrrolopyrrole compound, a cyanine compound, a squarylium compound is still more preferable, and a pyrrolopyrrole compound is still more preferable.

Examples of the pyrrolopyrrole compound include compounds described in paragraphs “0016” to “0058” of JP2009-263614A, compounds described in paragraphs “0037” to “0052” of JP2011-068731A, compounds described in paragraphs “0010” to “0033” of WO2015/166873A, the contents of which are incorporated herein by reference.

Examples of the squarylium compound include a compound described in paragraphs “0044” to “0049” of JP2011-208101A, a compound described in paragraphs “0060” and “0061” of JP6065169B, a compound described in paragraph “0040” of WO2016/181987A, a compound described in WO2013/133099A, a compound described in WO2014/088063A, a compound described in JP2014-126642A, a compound described in JP2016-146619A, a compound described in JP2015-176046A, a compound described in JP2017-025311A, a compound described in WO2016/154782A, a compound described in JP5884953B, a compound described in JP6036689B, a compound described in JP5810604B, and a compound described in JP2017-068120A, the contents of which are incorporated herein by reference.

In addition, examples of the cyanine compound include a compound described in paragraphs “0044” and “0045” of JP2009-108267A, a compound described in paragraphs “0026” to “0030” of JP2002-194040, a compound described in JP2015-172004A, a compound described in JP2015-172102A, a compound described in JP2008-088426A, and a compound described in JP2017-031394A, the contents of which are incorporated herein by reference.

Examples of the diimmonium compound include a compound described in JP2008-528706A, the content of which is incorporated herein by reference. Examples of the phthalocyanine compound include a compound described in paragraph “0093” of JP2012-077153A, oxytitaniumphthalocyanine described in JP2006-343631A, and a compound described in paragraphs “0013” to “0029” of JP2013-195480A, the contents of which are incorporated herein by reference. Examples of the naphthalocyanine compound include a compound described in paragraph “0093” of JP2012-077153A, the content of which is incorporated herein by reference.

In the present invention, as the infrared absorbing colorant, a commercially available product can also be used. Examples of the commercially available product include SDO-C33 (manufactured by Arimoto Chemical Co., Ltd.); EXCOLOR IR-14, EXCOLOR IR-10A, EXCOLOR TX-EX-801B, and EXCOLOR TX-EX-805K (manufactured by Nippon Shokubai Co., Ltd.); Shigenox NIA-8041, Shigenox NIA-8042, Shigenox NIA-814, Shigenox NIA-820, and Shigenox NIA-839 (manufactured by Hakkol Chemical Co., Ltd.); Epolite V-63, Epolight 3801, and Epolight 3036 (manufactured by Epolin Inc.); PRO-JET 825LDI (manufactured by Fujifilm Corporation); NK-3027 and NK-5060 (manufactured by Hayashibara Co., Ltd.); and YKR-3070 (manufactured by Mitsui Chemicals, Inc.).

From the viewpoint of reducing the thickness of the obtained film, the content of the coloring material is preferably 50 mass % or higher, more preferably 54 mass % or higher, still more preferably 58 mass % or higher, and still more preferably 60 mass % or higher with respect to the total solid content of the photosensitive composition. In a case where the content of the coloring material is 50 mass % or higher, a thin film having excellent spectral characteristics can be easily obtained. From the viewpoint of film forming properties, the upper limit is preferably 80 mass % or lower, more preferably 75 mass % or lower, and still more preferably 70 mass % or lower.

It is preferable that the coloring material used in the photosensitive composition according to the embodiment of the present invention includes at least one selected from a chromatic colorant or a black colorant. In addition, the content of the chromatic colorant and the black colorant is preferably 30 mass % or higher, more preferably 50 mass % or higher, and still more preferably 70 mass % or higher with respect to the total mass of the coloring material. The upper limit may be 100 mass % or may be 90 mass % or lower.

In addition, it is preferable that the coloring material used in the photosensitive composition according to the embodiment of the present invention includes at least a green colorant. In addition, the content of the green colorant is preferably 30 mass % or higher, more preferably 40 mass % or higher, and still more preferably 50 mass % or higher with respect to the total mass of the coloring material. The upper limit may be 100 mass % or may be 75 mass % or lower.

In the coloring material used in the photosensitive composition according to the embodiment of the present invention, the content of the pigment is preferably 50 mass % or higher, more preferably 70 mass % or higher, and still more preferably 90 mass % or higher with respect to the total mass of the coloring material. In a case where the content of the pigment is in the above-described range with respect to the total mass of the coloring material, a film having excellent heat resistance can be easily obtained.

In a case where the photosensitive composition according to the embodiment of the present invention is used as a composition for forming a colored pixel, the content of the chromatic colorant is preferably 50 mass % or higher, more preferably 54 mass % or higher, still more preferably 58 mass % or higher, and still more preferably 60 mass % or higher with respect to the total solid content of the photosensitive composition. In addition, the content of the chromatic colorant is preferably 25 mass % or higher, more preferably 45 mass % or higher, and still more preferably 65 mass % or higher with respect to the total mass of the coloring material. The upper limit may be 100 mass % or may be 75 mass % or lower. In addition, it is preferable that the coloring material includes at least a green colorant. In addition, the content of the green colorant is preferably 35 mass % or higher, more preferably 45 mass % or higher, and still more preferably 55 mass % or higher with respect to the total mass of the coloring material. The upper limit may be 100 mass % or may be 80 mass % or lower.

In a case where the photosensitive composition according to the embodiment of the present invention is used as a composition for a black pixel or for forming a light blocking film, the content of the black colorant (preferably the inorganic black colorant) is preferably 50 mass % or higher, more preferably 54 mass % or higher, and still more preferably 58 mass % or higher with respect to the total solid content of the photosensitive composition. In addition, the content of the black colorant is preferably 30 mass % or higher, more preferably 50 mass % or higher, and still more preferably 70 mass % or higher with respect to the total mass of the coloring material. The upper limit may be 100 mass % or may be 90 mass % or lower.

In a case where the photosensitive composition according to the embodiment of the present invention is used as a composition for forming a pixel of an infrared transmitting filter layer, it is preferable that the coloring material used in the present invention satisfies at least one of the following requirements (1) to (3).
(1): The coloring material includes two or more chromatic colorants, and a combination of the two or more chromatic colorants forms black. That is, it is preferable that the coloring material forms black using a combination of two or more colorants selected from a red colorant, a blue colorant, a yellow colorant, a violet colorant, and a green colorant.
(2): The coloring material includes an organic black colorant.
(3): In (1) or (2), the coloring material further includes an infrared absorbing colorant.

Examples of a preferable combination in the aspect (1) are as follows.
(1-1) An aspect in which the coloring material includes a red colorant and a blue colorant.
(1-2) An aspect in which the coloring material includes a red colorant, a blue colorant, and a yellow colorant.
(1-3) An aspect in which the coloring material includes a red colorant, a blue colorant, a yellow colorant, and a violet colorant.
(1-4) An aspect in which the coloring material includes a red colorant, a blue colorant, a yellow colorant, a violet colorant, and a green colorant.
(1-5) An aspect in which the coloring material includes a red colorant, a blue colorant, a yellow colorant, and a green colorant.
(1-6) An aspect in which the coloring material includes a red colorant, a blue colorant, and a green colorant.
(1-7) An aspect in which the coloring material includes a yellow colorant and a violet colorant.

In the aspect (2), it is preferable that the coloring material further includes a chromatic colorant. By using the organic black colorant in combination with a chromatic colorant, excellent spectral characteristics are likely to be obtained. Examples of the chromatic colorant which can be used in combination with the organic black colorant include a red colorant, a blue colorant, and a violet colorant. Among these, a red colorant or a blue colorant is preferable.

Among these colorants, one kind may be used alone, or two or more kinds may be used in combination. In addition, regarding a mixing ratio between the chromatic colorant and the organic black colorant, the amount of the chromatic colorant is preferably 10 to 200 parts by mass and more preferably 15 to 150 parts by mass with respect to 100 parts by mass of the organic black colorant.

In the aspect (3), the content of the infrared absorbing colorant is preferably 5% to 40 mass % with respect to the total mass of the coloring material. The upper limit is preferably 30 mass % or lower and more preferably 25 mass % or lower. The lower limit is preferably 10 mass % or higher and more preferably 15 mass % or higher.

### <<Polymerizable Monomer>>

The photosensitive composition according to the embodiment of the present invention includes a polymerizable monomer. Examples of the polymerizable monomer include a radically polymerizable monomer and a cationically polymerizable monomer. Examples of the radically polymerizable monomer include a compound having an ethylenically unsaturated bond group such as a vinyl group, a (meth)allyl group, or a (meth)acryloyl group. Examples of the cationically polymerizable monomer include a compound having a cyclic ether group such as an epoxy group or an oxetanyl group. From the viewpoint that higher curing properties can be easily obtained in a case where the photosensitive composition is exposed to light having a wavelength of 300 nm or shorter, it is preferable that the polymerizable monomer is a radically polymerizable monomer.

The polymerizable monomer is preferably a polymerizable monomer having two or more functional groups, more preferably a polymerizable monomer having 2 to 15 functional groups, still more preferably a polymerizable monomer having 2 to 10 functional groups, and still more preferably a polymerizable monomer having 2 to 6 functional groups.

The molecular weight of the polymerizable monomer is preferably lower than 2000, more preferably 1500 or lower, and still more preferably 1000 or lower. The lower limit is preferably 100 or higher and more preferably 150 or higher.

In addition, in the present invention, it is also preferable that a polymerizable monomer having a fluorene skeleton is used as the polymerizable monomer. The polymerizable monomer having a fluorene skeleton has high absorbance with respect to light having a wavelength of 300 nm or shorter. By irradiating this polymerizable monomer with light having a wavelength of 300 nm or shorter, it is presumed that an active species such as a radical can be easily generated from the polymerizable monomer. As a result, higher curing properties can be obtained in a case where the photosensitive composition is exposed to light having a wavelength of 300 nm or shorter.

Examples of the polymerizable monomer having a fluorene skeleton include a compound having a partial structure represented by the following Formula (Fr).

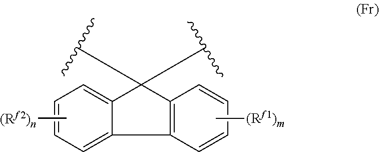

In the formula, a wave line represents a direct bond, R^{f1} and R^{f2} each independently represent a substituent, and m and n each independently represent an integer of 0 to 5. In a case where m represents 2 or more, m R^{f1} 's may be the same as or different from each other, or two R^{f1}'s among m R^{f1} 's may be bonded to each other to form a ring. In a case where n represents 2 or more, n R^{f2}'s may be the same as or different from each other, or two R^{f2} 's among n R^{f2}'s may be bonded to each other to form a ring. Examples of the substituent represented by R^{f1} and R^{f2} include a halogen atom, a cyano group, a nitro group, an alkyl group, an aryl group, a heteroaryl group, —OR^{f11}, —COR^{f12}, —COOR^{f13}, —OCOR^{f14}, —NR^{f15}R^{f16}, —NHCOR^{f17}, —CONR^{f18}R^{f19}, —NHCONR^{f20}R^{f21}, —NHCOOR^{f22}, —SR^{f23}, —SO₂R^{f4}, —SO₂OR^{f25}, —NHSO₂R^{f26}, and —SO₂NR^{f27}R^{f28}. R^{f11} to R^{f28} each independently represents a hydrogen atom, an alkyl group, an aryl group, or a heteroaryl group.

The polymerizable group value of the polymerizable monomer is preferably 2 mmol/g or higher, more preferably 6 mmol/g or higher, and still more preferably 10 mmol/g or higher. The upper limit is preferably 20 mmol/g or lower. In a case where the polymerizable group value of the polymerizable monomer is 2 mmol/g or higher, the curing properties of the photosensitive composition are excellent. The polymerizable group value of the polymerizable monomer can be calculated by dividing the number of polymerizable groups in one molecule of the polymerizable monomer by the molecular weight of the polymerizable monomer.

In addition, in a case where the polymerizable monomer is a compound having an ethylenically unsaturated bond group, the ethylenically unsaturated bond group value (hereinafter, also referred to as “C═C value”) of the polymerizable monomer is preferably 2 mmol/g or higher, more preferably 6 mmol/g or higher, and still more preferably 10 mol/g or higher. The upper limit is preferably 13 mmol/g or lower. The C═C value of the polymerizable monomer can be calculated by dividing the number of ethylenically unsaturated bond groups in one molecule of the polymerizable monomer by the molecular weight of the polymerizable monomer.

### (Radically Polymerizable Monomer)

The radically polymerizable monomer is preferably a compound having two or more ethylenically unsaturated bond groups (compound having two or more functional groups), more preferably a compound having 2 to 15 ethylenically unsaturated bond groups (compound having 2 to 15 functional groups), still more preferably a compound having 2 to 10 ethylenically unsaturated bond groups (compound having 2 to 10 functional groups), and still more preferably a compound having 2 to 6 ethylenically unsaturated bond groups (compound having 2 to 6 functional groups). Specifically, the radically polymerizable monomer is preferably a (meth)acrylate compound having two or more functional groups, more preferably a (meth)acrylate compound having 2 to 15 functional groups, still more preferably a (meth)acrylate compound having 2 to 10 functional groups, and still more preferably a (meth)acrylate compound having 2 to 6 functional groups. Specific examples of the polymerizable monomer include compounds described in paragraphs “0095” to “0108” of JP2009-288705A, paragraph “0227” of JP2013-29760 and paragraphs “0254” to “0257” of JP2008-292970A, the contents of which are incorporated herein by reference.

The radically polymerizable monomer is preferably a radically polymerizable monomer having a fluorene skeleton and more preferably a radically polymerizable monomer having a partial structure represented by Formula (Fr). In addition, the radically polymerizable monomer having a fluorene skeleton is preferably a compound having two or more ethylenically unsaturated bond groups, more preferably a compound having 2 to 15 ethylenically unsaturated bond groups, still more preferably a compound having 2 to 10 ethylenically unsaturated bond groups, and still more preferably a compound having 2 to 6 ethylenically unsaturated bond groups. Specific examples of the radically polymerizable monomer having a fluorene skeleton include a compound having the following structure. In addition, examples of a commercially available product of the radically polymerizable monomer having a fluorene skeleton include OGSOL EA-0200 and EA-0300 (manufactured by Osaka Gas Chemicals Co., Ltd., a (meth)acrylate monomer having a fluorene skeleton).

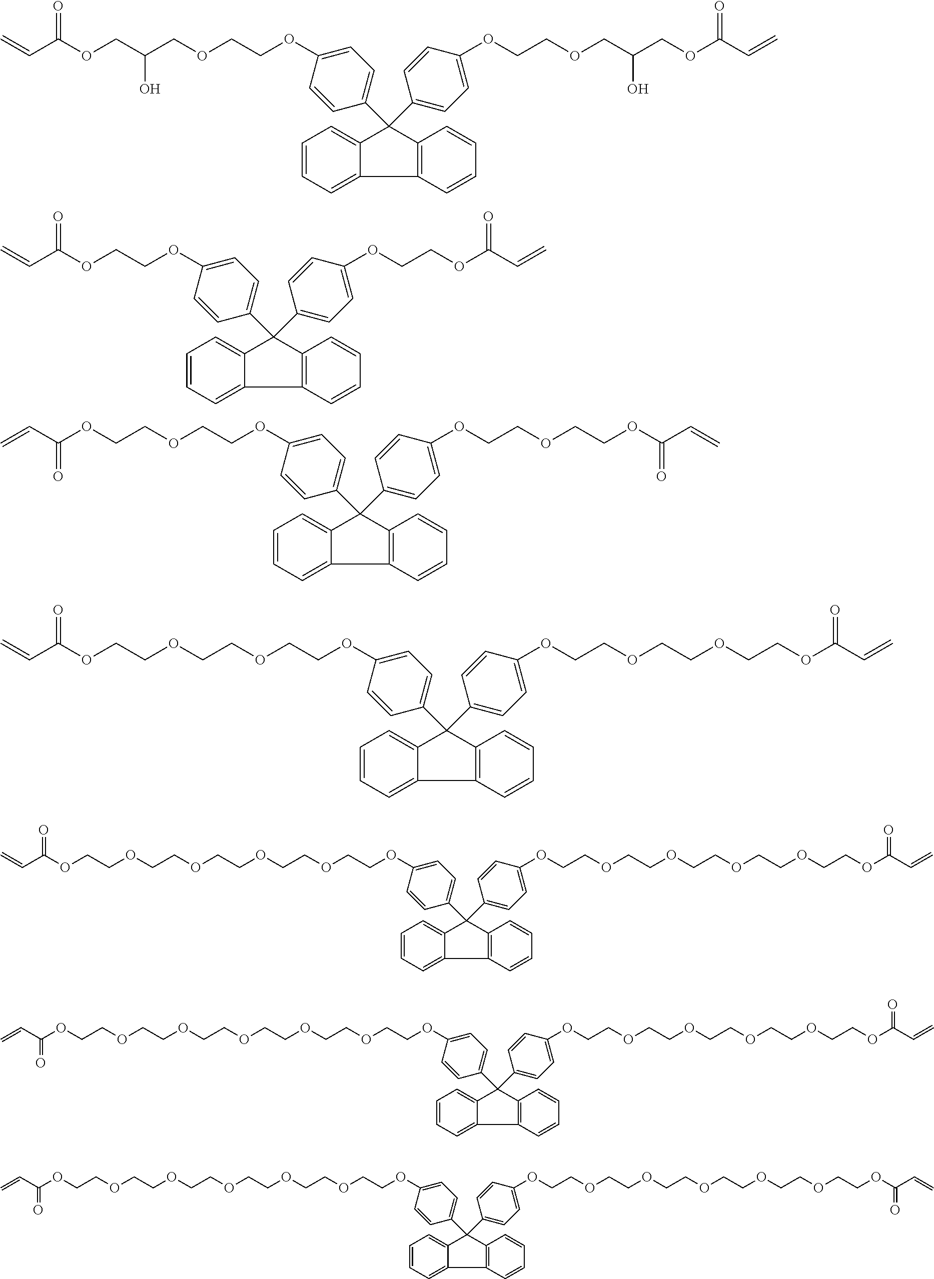

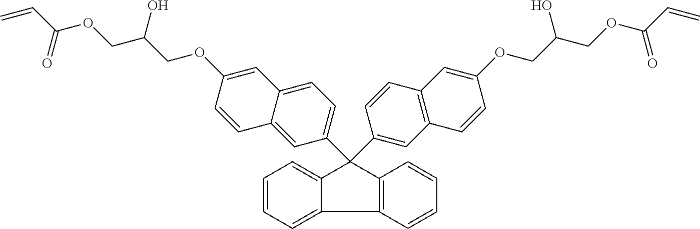 [SMILES: C=CC(=O)OCC(O)COc1ccc2cc(C3(c4ccc5cc(OCC(O)COC(=O)C=C)ccc5c4)c4ccccc4-c4ccccc43)ccc2c1]

As the radically polymerizable monomer, compounds represented by the following Formulae (MO-1) to (MO-6) can also be preferably used. In a case where T in the formulae represents an oxyalkylene group, a terminal thereof on a carbon atom side is bonded to R.

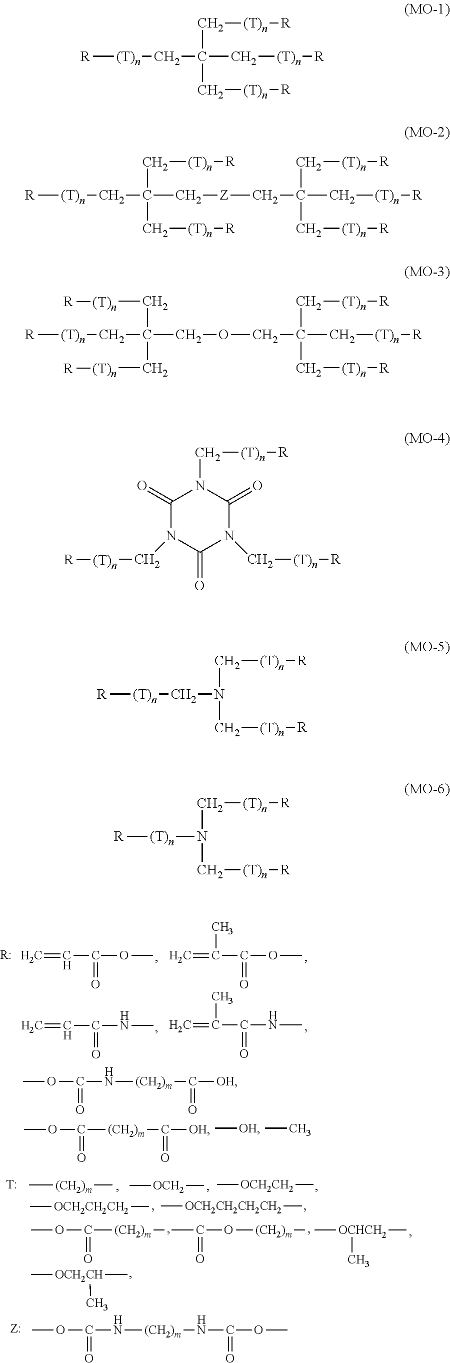

In the formulae, n represents 0 to 14, and m represents 1 to 8. A plurality of R's and a plurality of T's which are present in one molecule may be the same as or different from each other.

At least one of a plurality of R's which are present in each of the compounds represented by Formula (MO-1) to (MO-6) represents —OC(═O)CH═CH₂, —OC(═O)C(CH₃)═CH₂, —NC(═O)CH═CH₂, or —NHC(═O)C(CH₃)═CH₂.

Specific examples of the polymerizable compounds represented by Formulae (MO-1) to (MO-6) include compounds described in paragraphs “0248” to “0251” of JP2007-269779A.

It is also preferable that the radically polymerizable monomer is a compound having a caprolactone structure. As the compound having a caprolactone structure, a compound represented by the following Formula (Z-1) is preferable.

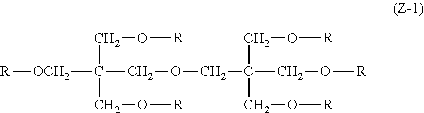

In Formula (Z-1), all of six R's represent a group represented by Formula (Z-2), or one to five R's among the six R's represent a group represented by Formula (Z-2) and the remaining R's represent a group represented by Formula (Z-3), an acid group, or a hydroxy group.

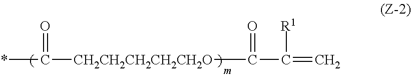

In Formula (Z-2), R¹ represents a hydrogen atom or a methyl group, m represents an integer of 1 or 2, and “*” represents a direct bond.

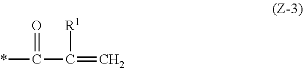

In Formula (Z-3), R¹ represents a hydrogen atom or a methyl group, and “*” represents a direct bond.

As the radically polymerizable monomer, a compound represented by Formula (Z-4) or (Z-5) can also be used.

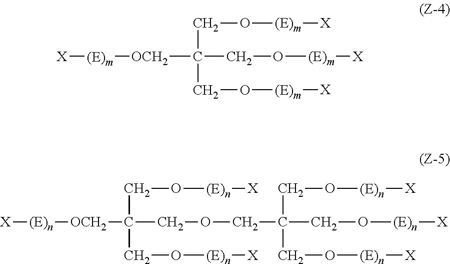

In Formulae (Z-4) and (Z-5), E's each independently represent —((CH₂)_{y}CH₂O)— or —((CH₂)_{y}CH(CH₃)O)—, y's each independently represent an integer of 0 to 10, and X's each independently represent a (meth)acryloyl group, a hydrogen atom, or a carboxyl group. In Formula (Z-4), the total number of (meth)acryloyl groups is 3 or 4, m's each independently represent an integer of 0 to 10, and the sum of m's is an integer of 0 to 40. In Formula (Z-5), the total number of (meth)acryloyl groups is 5 or 6, n's each independently represent an integer of 0 to 10, and the sum of n's is an integer of 0 to 60.

In Formula (Z-4), m represents preferably an integer of 0 to 6 and more preferably an integer of 0 to 4. In addition, the sum of m's is preferably an integer of 2 to 40, more preferably an integer of 2 to 16, and still more preferably an integer of 4 to 8.

In Formula (Z-5), n represents preferably an integer of 0 to 6 and more preferably an integer of 0 to 4. In addition, the sum of n's is preferably an integer of 3 to 60, more preferably an integer of 3 to 24, and still more preferably an integer of 6 to 12.

In addition, it is preferable that, in —((CH₂)_{y}CH₂O)— or —((CH₂)_{y}CH(CH₃)O)— of Formula (Z-4) or (Z-5), a terminal thereof on an oxygen atom side is bonded to X.

In the present invention, it is preferable that, as the radically polymerizable monomer, the radically polymerizable monomer having a fluorene skeleton (preferably a radically polymerizable monomer having 2 to 15 functional groups that has a fluorene skeleton, more preferably a radically polymerizable monomer having 2 to 10 functional groups that has a fluorene skeleton, still more preferably a radically polymerizable monomer having 2 to 6 functional groups that has a fluorene skeleton, and still more preferably a radically polymerizable monomer having 2 functional groups that has a fluorene skeleton) and a radically polymerizable monomer not having a fluorene skeleton (preferably a radically polymerizable monomer having 3 or more functional groups and more preferably a radically polymerizable monomer having 3 to 15 functional groups) are used in combination. In this aspect, the polymerizable monomer can be efficiently caused to react, and higher curing properties can be easily obtained.

### (Cationically Polymerizable Monomer)

The cationically polymerizable monomer is preferably a compound having two or more cyclic ether groups (compound having two or more functional groups), more preferably a compound having 2 to 15 cyclic ether groups (compound having 2 to 15 functional groups), still more preferably a compound having 2 to 10 cyclic ether groups (compound having 2 to 10 functional groups), and still more preferably a compound having 2 to 6 cyclic ether groups (compound having 2 to 6 functional groups). As specific examples, compounds described in paragraphs “0034” to “0036” of JP2013-011869A and paragraphs “0085” to “0090” of JP2014-089408A can also be used. The contents of this specification are incorporated herein by reference.

Examples of the cationically polymerizable monomer include a compound represented by the following Formula (EP1).

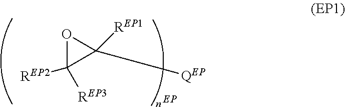

In Formula (EP1), R^{EP1} to R^{EP3} each independently represent a hydrogen atom, a halogen atom, or an alkyl group. The alkyl group may have a cyclic structure or may have a substituent. In addition, R^{EP1} and R^{EP2}, or R^{EP2} and R^{EP3} may be bonded to each other to form a ring structure. Q^{EP} represents a single bond or a n^{EP}-valent organic group. R^{EP1} to R^{EP3} may be bonded to Q^{EP} to form a ring structure. n^{EP} represents an integer of 2 or more, preferably 2 to 10, and more preferably 2 to 6. In a case where Q^{EP} represents a single bond, n^{EP} represents 2. The details of R^{EP1} to R^{EP3} and Q^{EP} can be found in paragraphs “0087” and “0088” of JP2014-089408A, the content of which is incorporated herein by reference. Specific examples of the compound represented by Formula (EP1) include a compound described in paragraph “0090” of JP2014-089408A and a compound described in paragraph “0151” of JP2010-054632A, the contents of which are incorporated herein by reference.

Examples of a commercially available product of the cationically polymerizable monomer include ADEKA GLYCILOL series manufactured by Adeka Corporation (for example, ADEKA GLYCILOL ED-505) and EPOLEAD series manufactured by Daicel Corporation (for example, EPOLEAD GT401).

The content of the polymerizable monomer is preferably 13 mass % or lower, more preferably 10 mass % or lower, still more preferably 8 mass % or lower, and still more preferably 6 mass % or lower with respect to the total solid content of the photosensitive composition. From the viewpoint of curing properties, the lower limit is preferably 1 mass % or higher, more preferably 2 mass % or higher, and still more preferably 3 mass % or higher.

In addition, the content of the polymerizable monomer is preferably 50 mass % or higher, more preferably 60 mass % or higher, and still more preferably 70 mass % or higher with respect to the total content of the polymerizable monomer and the photopolymerization initiator. The upper limit may be 100 mass %, and from the viewpoints of developability and curing properties, is preferably 95 mass % or lower, more preferably 90 mass % or lower, still more preferably 85 mass % or lower, and still more preferably 80 mass % or lower.

In addition, the content of the polymerizable monomer is preferably 20 parts by mass or less, more preferably 10 parts by mass or less, and still more preferably 5 parts by mass or less with respect to 100 parts by mass of the coloring material. In addition, the lower limit is preferably 1 part by mass or more.

### <<Photopolymerization Initiator>>

It is preferable that the photosensitive composition according to the embodiment of the present invention includes a photopolymerization initiator. Examples of the photopolymerization initiator include a photoradical polymerization initiator and a photocationic polymerization initiator. It is preferable that the photopolymerization initiator is selected and used according to the kind of the polymerizable monomer. In a case where the radically polymerizable monomer is used as the polymerizable monomer, it is preferable that the photoradical polymerization initiator is used as the photopolymerization initiator. In a case where the cationically polymerizable monomer is used as the polymerizable monomer, it is preferable that the photocationic polymerization initiator is used as the photopolymerization initiator. The photopolymerization initiator is preferably a compound that reacts with light having a wavelength of 300 nm or shorter to generate an active species and more preferably a compound that reacts with light having a wavelength of 300 nm or shorter to generate a radical.

It is also preferable that the photopolymerization initiator is a compound having a quantum yield of 15% or higher with respect to light having a wavelength of 265 nm. In this specification, the quantum yield of the photopolymerization initiator refers to a value obtained by dividing the number of decomposed molecules by the number of absorbed photons. Regarding the number of absorbed photons, the number of irradiated photons is obtained from an exposure time using a KrF ray approximating light source (wavelength: 265 nm, intensity: 3 mW), an average absorbance at 265 nm before and after exposure is converted into a transmittance, and the number of irradiated photons is multiplied by (1-transmittance) to obtain the number of absorbed photons. Regarding the number of decomposed molecules, a decomposition rate of the photopolymerization initiator is obtained from the absorbance of the photopolymerization initiator after exposure, and the decomposition rate is multiplied by the number of molecules present in the film to obtain the number of decomposed molecules. Examples of the compound having a quantum yield of 15% or higher with respect to light having a wavelength of 265 nm include IRGACURE-OXE01, OXE02, and OXE03 (all of which are manufactured by BASF SE).

It is preferable that the photopolymerization initiator includes at least one compound selected from an alkylphenone compound, an acylphosphine compound, a benzophenone compound, a thioxanthone compound, a triazine compound, or an oxime compound, and it is more preferable that the photoinitiator B includes an oxime compound.

Examples of the alkylphenone compound include a benzyldimethylketal compound, an α-hydroxyalkylphenone compound, and an α-aminoalkylphenone compound.

Examples of the benzyldimethylketal compound include 2,2-dimethoxy-2-phenylacetophenone. Examples of a commercially available product include IRGACURE-651 (manufactured by BASF SE).

Examples of the α-hydroxyalkylphenone compound include 1-hydroxy-cyclohexyl-phenyl-ketone, 2-hydroxy-2-methyl-1-phenyl-propane-1-one, 1-[4-(2-hydroxyethoxy)-phenyl]-2-hydroxy-2-methyl-1-propane-1-one, and 2-hydroxy-1-{4-[4-(2-hydroxy-2-methyl-propionyl)-benzyl]phenyl}-2-methyl-propane-1-one. Examples of a commercially available product of the α-hydroxyalkylphenone compound include IRGACURE-184, DAROCUR-1173, IRGACURE-500, IRGACURE-2959, and IRGACURE-127 (all of which are manufactured by BASF SE).

Examples of the α-aminoalkylphenone compound include 2-methyl-1-(4-methylthiophenyl)-2-morpholinopropan-1-one, 2-benzyl-2-dimethylamino-1-(4-morpholinophenyl)-1-butanone, and 2-dimethylamino-2-[(4-methylphenyl)methyl]-1-[4-(4-morpholinyl)phenyl]-1-butanone. Examples of a commercially available product of the α-aminoalkylphenone compound include IRGACURE-907, IRGACURE-369, and IRGACURE-379 (all of which are manufactured by BASF SE).

Examples of the acylphosphine compound include 2,4,6-trimethylbenzoyl-diphenyl-phosphine oxide and bis(2,4,6-trimethylbenzoyl)-phenylphosphine oxide. Examples of a commercially available product of the acylphosphine compound include IRGACURE-819 and IRGACURE-TPO (all of which are manufactured by BASF SE).

Examples of the benzophenone compound include benzophenone, methyl o-benzoylbenzoate, 4-phenylbenzophenone, 4-benzoyl-4′-methyldiphenyl sulfide, 3,3′,4,4′-tetra(t-butyl peroxy carbonyl)benzophenone, and 2,4,6-trimethyl benzophenone.

Examples of the thioxanthone compound include 2-isopropylthioxanthone, 4-isopropylthioxanthone, 2,4-diethylthioxanthone, 2,4-dichlorothioxanthone, and 1-chloro-4-propoxythioxanthone.

Examples of the triazine compound include 2,4-bis(trichloromethyl)-6-(4-methoxyphenyl)-1,3,5-triazine, 2,4-bis(trichloromethyl)-6-(4-methoxynaphthyl)-1,3,5-triazine, 2,4-bis(trichloromethyl)-6-piperonyl-1,3,5-triazine, 2,4-bis(trichloromethyl)-6-(4-methoxyscrew)-1,3,5-triazine, 2,4-bis(trichloromethyl)-6-[2-(5-methylfuran-2-yl)ethenyl]-1,3,5-triazine, 2,4-bis(trichloromethyl)-6-[2-(furan-2-yl)ethenyl]-1,3,5-triazine, 2,4-bis(trichloromethyl)-6-[2-(4-di ethylamino-2-methyl phenyl)ethenyl]-1,3,5-triazine, and 2,4-bis(trichloromethyl)-6-[2-(3,4-dimethoxyphenyl)ethenyl]-1,3,5-triazine.

Examples of the oxime compound include a compound described in JP2001-233842A, a compound described in JP2000-080068A, a compound described in JP2006-342166A, a compound described in J. C. S. Perkin II (1979, pp. 1653 to 1660), a compound described in J. C. S. Perkin II (1979, pp. 156 to 162), a compound described in Journal of Photopolymer Science and Technology (1995, pp. 202 to 232), a compound described in JP2000-066385A, a compound described in JP2000-080068A, a compound described in JP2004-534797A, a compound described in JP2006-342166A, a compound described in JP2017-019766A, a compound described in JP6065596B, a compound described in WO2015/152153A, and a compound described in WO2017/051680A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product of the oxime compound include IRGACURE-OXE01, IRGACURE-OXE02, IRGACURE-OXE03, or IRGACURE-OXE04 (all of which are manufactured by BASF SE), TR-PBG-304 (manufactured by Changzhou Tronly New Electronic Materials Co., Ltd.), and ADEKA OPTOMER N-1919 (manufactured by Adeka Corporation, a photopolymerization initiator 2 described in JP2012-014052A). As the oxime compound, a compound having no colorability or a compound having high transparency that is not likely to discolor other components can also be preferably used. Examples of a commercially available product of the oxime compound include ADEKAARKLS NCI-730, NCI-831, and NCI-930 (all of which are manufactured by Adeka Corporation).

In the present invention, an oxime compound having a fluorene ring can also be used as the photopolymerization initiator. Specific examples of the oxime compound having a fluorene ring include a compound described in JP2014-137466A. The content of this specification is incorporated herein by reference.

In the present invention, an oxime compound having a fluorine atom can also be used as the photopolymerization initiator. Specific examples of the oxime compound having a fluorine atom include a compound described in JP2010-262028A, Compound 24 and 36 to 40 described in JP2014-500852A, and Compound (C-3) described in JP2013-164471A. The content of this specification is incorporated herein by reference.

In the present invention, as the photopolymerization initiator, an oxime compound having a nitro group can be used. It is preferable that the oxime compound having a nitro group is a dimer. Specific examples of the oxime compound having a nitro group include a compound described in paragraphs “0031” to “0047” of JP2013-114249A and paragraphs “0008” to “0012” and “0070” to “0079” of JP2014-137466A, a compound described in paragraphs “0007” to 0025” of JP4223071B, and ADEKA ARKLS NCI-831 (manufactured by Adeka Corporation).

In the present invention, as the photopolymerization initiator, an oxime compound having a benzofuran skeleton can also be used. Specific examples include OE-01 to OE-75 described in WO2015/036910A.

Hereinafter, specific examples of the oxime compound which are preferably used in the present invention are shown below, but the present invention is not limited thereto.

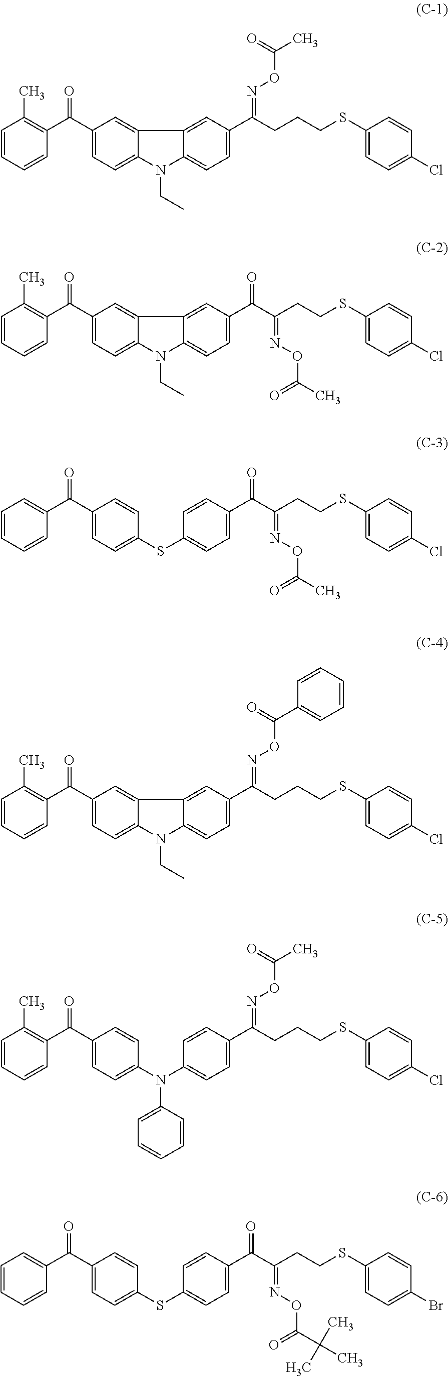 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

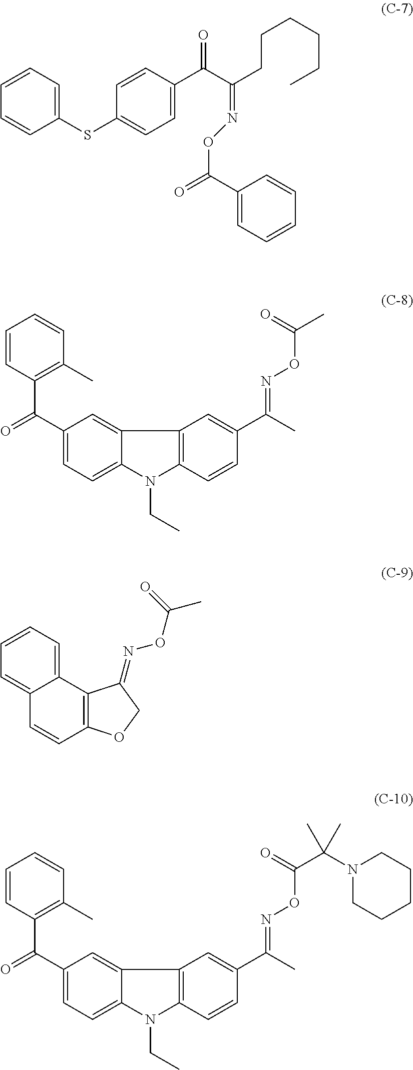 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21]

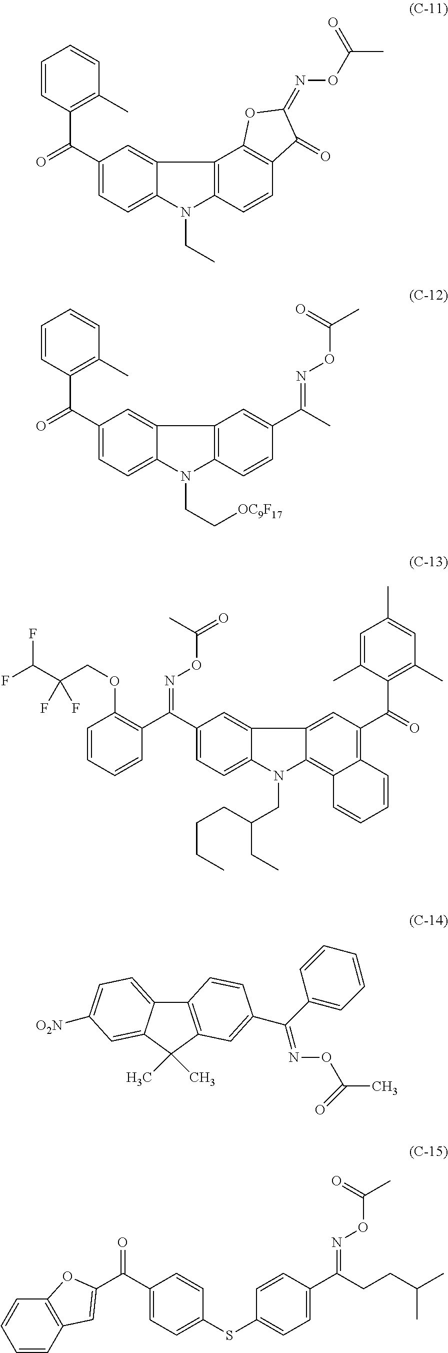

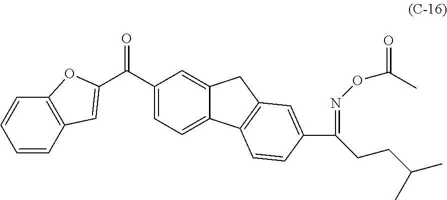 [SMILES: CC(=O)O/N=C(\CCC(C)C)c1ccc2c(c1)Cc1cc(C(=O)c3cc4ccccc4o3)ccc1-2]

In the present invention, as the photopolymerization initiator, a photopolymerization initiator having two functional groups or three or more functional groups may be used. By using this photopolymerization initiator, two or more active species such as radicals are generated from one molecule of the photopolymerization initiator. Therefore, excellent sensitivity can be obtained. In addition, in a case where a compound having an asymmetric structure is used, crystallinity deteriorates, solubility in a solvent or the like is improved, precipitation is not likely to occur over time, and temporal stability of the photosensitive composition can be improved. Specific examples of the photopolymerization initiator having two functional groups or three or more functional groups include a dimer of an oxime compound described in JP2010-527339A, JP2011-524436A, WO2015/004565A, paragraphs “0412” to “0417” of JP2016-532675A, or paragraphs “0039” to “0055” of WO2017/033680A, a compound (E) and a compound (G) described in JP2013-522445A, Cmpd 1 to 7 described in WO2016/034963A, an oxime ester photoinitiator described in paragraph “0007” of JP2017-523465A, a photoinitiator described in paragraphs “0020” to “0033” of JP2017-167399A, and a photopolymerization initiator (A) described in paragraphs “0017” to “0026” of JP2017-151342A.

In addition, in the present invention, a pinacol compound can also be used as the photopolymerization initiator. It is preferable that the pinacol compound is a benzopinacol compound. Specific examples of the pinacol compound include benzopinacol, 1,2-dimethoxy-1,1,2,2-tetraphenylethane, 1,2-diethoxy-1,1,2,2-tetraphenylethane, 1,2-diphenoxy-1,1,2,2-tetraphenylethane, 1,2-dimethoxy-1,1,2,2-tetra(4-methylphenyl)ethane, 1,2-diphenoxy-1,1,2,2-tetra(4-methoxyphenyl)ethane, 1,2-bis(trimethylsilloxy)-1,1,2,2-tetraphenylethane, 1,2-bis(triethylsilloxy)-1,1,2,2-tetraphenylethane, 1,2-bis(t-butyldimethylsilloxy)-1,1,2,2-tetraphenylethane, 1-hydroxy-2-trimethylsilloxy-1,1,2,2-tetraphenylethane, 1-hydroxy-2-triethylsilloxy-1,1,2,2-tetraphenylethane, and 1-hydroxy-2-t-butyldimethylsilloxy-1,1,2,2-tetraphenylethane. In addition, the details of the pinacol compound can be found in JP2014-523939A and JP2014-521772A, the contents of which are incorporated herein by reference.

From the viewpoint of easily suppressing pattern thickening, the content of the photopolymerization initiator is preferably 5 mass % or lower, more preferably 4 mass % or lower, and still more preferably 3 mass % or lower with respect to the total solid content of the photosensitive composition. From the viewpoint of curing properties, the lower limit is preferably 0.1 mass % or higher, more preferably 0.3 mass % or higher, and still more preferably 0.5 mass % or higher. In addition, from the viewpoint of easily suppressing pattern thickening, the content of the photopolymerization initiator is preferably 5 parts by mass or less, more preferably 3.5 parts by mass or less, and still more preferably 2 parts by mass or less with respect to 100 parts by mass of the coloring material. From the viewpoint of curing properties, the lower limit is preferably 0.5 parts by mass or more and more preferably 1 part by mass or more. In a case where the photosensitive composition according to the embodiment of the present invention includes two or more photopolymerization initiators, it is preferable that the total content of the two or more photopolymerization initiators is in the above-described range.

In addition, the photosensitive composition according to the embodiment of the present invention may not substantially include the photopolymerization initiator. The photosensitive composition according to the embodiment of the present invention not substantially including the photopolymerization initiator represents that the content of the photopolymerization initiator is 0.1 mass % or lower, preferably 0.05 mass % or lower, and more preferably 0 mass % with respect to the total solid content of the photosensitive composition.

### <<Resin>>

The photosensitive composition according to the embodiment of the present invention may include a resin. The resin according to the embodiment of the present invention refers to an organic compound having a molecular weight of 2000 or higher other than a coloring material. The resin is added, for example, in order to disperse particles of the pigments and the like in the composition or to be added as a binder. The resin which is mainly used to disperse particles of the pigments and the like will also be called a dispersant. However, the above-described uses of the resin are merely exemplary, and the resin can be used for purposes other than the uses.

The weight-average molecular weight (Mw) of the resin is preferably 2000 to 2000000. The upper limit is preferably 1000000 or lower and more preferably 500000 or lower. The lower limit is preferably 3000 or higher and more preferably 5000 or higher.

Examples of the resin include a (meth)acrylic resin, an epoxy resin, an enethiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide imide resin, a polyolefin resin, a cyclic olefin resin, a polyester resin, and a styrene resin. Among these resins, one kind may be used alone, or a mixture of two or more kinds may be used.

Examples of the epoxy resin include an epoxy resin which is a glycidyl-etherified product of a phenol compound, an epoxy resin which is a glycidyl-etherified product of various novolac resins, an alicyclic epoxy resin, an aliphatic epoxy resin, a heterocyclic epoxy resin, a glycidyl ester epoxy resin, a glycidyl amine epoxy resin, an epoxy resin which is a glycidylated product of a halogenated phenol, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3300 g/eq, more preferably 310 to 1700 g/eq, and still more preferably 310 to 1000 g/eq. Examples of a commercially available product of the epoxy resin include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-110S, G-2050M, G-01100, or G-01758 (manufactured by NOF Corporation, an epoxy group-containing polymer). As the epoxy resin, epoxy resins described in paragraphs “0153” to “0155” of JP2014-043556A and paragraph “0092” of JP2014-089408A can also be used, the contents of which are incorporated herein by reference.

As the cyclic olefin resin, a norbornene resin can be preferably used from the viewpoint of improving heat resistance. Examples of a commercially available product of the norbornene resin include ARTON series (for example, ARTON F4520, manufactured by JSR Corporation).

In addition, as the resin, a resin described in Examples of WO2016/088645A, a resin described in JP2017-057265A, a resin described in JP2017-032685A, a resin described in JP2017-075248A, or a resin described in JP2017-066240A can also be used, the contents of which are incorporated herein by reference. In addition, a resin having a fluorene skeleton can also be preferably used. Examples of the resin having a fluorene skeleton include a resin having the following structure. In the following structural formula, A represents a residue of a carboxylic dianhydride selected from pyromellitic dianhydride, benzophenone tetracarboxylic dianhydride, biphenyl tetracarboxylic dianhydride, or diphenyl ether tetracarboxylic dianhydride, and M represents a phenyl group or a benzyl group. The details of the resin having a fluorene skeleton can be found in US2017/0102610A, the content of which is incorporated herein by reference.

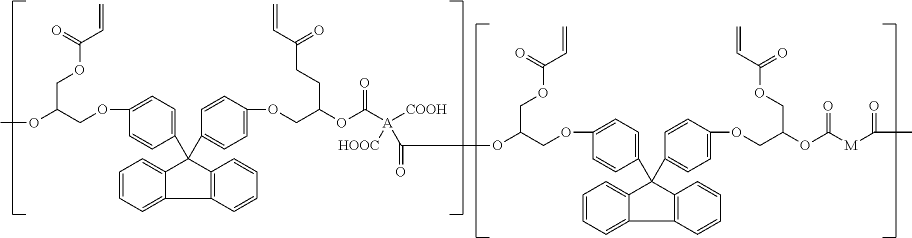

In the present invention, it is preferable that a resin having an acid group is used as the resin. In this aspect, the developability of the photosensitive composition can be improved, and a pixel having excellent rectangularity can be easily formed. Examples of the acid group include a carboxyl group, a phosphate group, a sulfo group, and a phenolic hydroxy group. Among these, a carboxyl group is preferable. The resin having an acid group can be used as, for example, an alkali-soluble resin.

It is preferable that the resin having an acid group further includes a repeating unit having an acid group at a side chain, and it is more preferable that the content of the repeating unit having an acid group at a side chain is preferably 5 to 70 mol % with respect to all the repeating units of the resin. The upper limit of the content of the repeating unit having an acid group at a side chain is preferably 50 mol % or lower and more preferably 30 mol % or lower. The lower limit of the content of the repeating unit having an acid group at a side chain is preferably 10 mol % or higher and more preferably 20 mol % or higher.

It is preferable that the resin having an acid group is a resin which includes a repeating unit having a carboxyl group at a side chain. Specific examples of the resin include an alkali-soluble phenol resin such as a methacrylic acid copolymer, an acrylic acid copolymer, an itaconic acid copolymer, a crotonic acid copolymer, a maleic acid copolymer, a partially esterified maleic acid copolymer, or a novolac resin, an acidic cellulose derivative having a carboxyl group at a side chain thereof, and a resin obtained by adding an acid anhydride to a polymer having a hydroxy group. In particular, a copolymer of (meth)acrylic acid and another monomer which is copolymerizable with the (meth)acrylic acid is preferable as the alkali-soluble resin. Examples of the monomer which is copolymerizable with the (meth)acrylic acid include an alkyl (meth)acrylate, an aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, and cyclohexyl (meth)acrylate. Examples of the vinyl compound include styrene, α-methylstyrene, vinyl toluene, glycidyl methacrylate, acrylonitrile, vinyl acetate, N-vinylpyrrolidone, tetrahydrofurfuryl methacrylate, a polystyrene macromonomer, and a polymethyl methacrylate macromonomer. Examples of other monomers include a N-position-substituted maleimide monomer described in JP1998-300922A (JP-H10-300922A) such as N-phenylmaleimide or N-cyclohexylmaleimide. As the other monomer which is copolymerizable with the (meth)acrylic acid, one kind may be used alone, or two or more kinds may be used in combination. The details of the resin having an acid group can be found in paragraphs “0558” to “0571” of JP2012-208494A (corresponding to paragraphs “0685” to “0700” of US2012/0235099A) and paragraphs “0076” to “0099” of JP2012-198408A, the contents of which are incorporated herein by reference. In addition, as the resin having an acid group, a commercially available product may also be used. Examples of the commercially available product include ACRYBASE FF-426 (manufactured by Fujikura Kasei Co., Ltd.).

The acid value of the resin having an acid group is preferably 30 to 200 mgKOH/g. The lower limit is preferably 50 mgKOH/g or higher, more preferably 70 mgKOH/g or higher, and still more preferably 100 mgKOH/g or higher. The upper limit is preferably 180 mgKOH/g or lower and more preferably 150 mgKOH/g or lower.

In the present invention, it is preferable that a resin having a polymerizable group is used as the resin. In this aspect, a pixel having excellent rectangularity and excellent adhesiveness with the support is likely to be formed. Examples of the polymerizable group include an ethylenically unsaturated bond group such as a vinyl group, a (meth)allyl group, or a (meth)acryloyl group. Among these, a (meth)acryloyl group is preferable.

The weight-average molecular weight of the resin having a polymerizable group is preferably 5000 to 20000. The upper limit is preferably 17000 or lower and more preferably 14000 or lower. The lower limit is preferably 7000 or higher and more preferably 9000 or higher. In a case where the weight-average molecular weight of the resin having a polymerizable group is in the above-described range, a pixel having excellent developability and rectangularity can be easily formed.

The polymerizable group value of the resin having a polymerizable group is preferably 0.5 to 3 mmol/g. The upper limit is preferably 2.5 mmol/g or lower and more preferably 2 mmol/g or lower. The lower limit is preferably 0.9 mmol/g or higher and more preferably 1.2 mmol/g or higher. The polymerizable group value of the resin refers to a numerical value representing the molar amount of the polymerizable group value per 1 g of the solid content of the resin. In addition, the C═C value of the resin having a polymerizable group is preferably 0.6 to 2.8 mmol/g. The upper limit is preferably 2.3 mmol/g or lower and more preferably 1.8 mmol/g or lower. The lower limit is preferably 1.0 mmol/g or higher and more preferably 1.3 mmol/g or higher. The C═C value of the resin refers to a numerical value representing the molar amount of the ethylenically unsaturated bond group per 1 g of the solid content of the resin.

It is preferable that the resin having a polymerizable group further includes a repeating unit having a polymerizable group (preferably an ethylenically unsaturated bond group) at a side chain, and it is more preferable that the content of the repeating unit having a polymerizable group at a side chain is preferably 5 to 80 mol % with respect to all the repeating units of the resin. The upper limit of the content of the repeating unit having a polymerizable group at a side chain is preferably 60 mol % or lower and more preferably 40 mol % or lower. The lower limit of the content of the repeating unit having a polymerizable group at a side chain is preferably 15 mol % or higher and more preferably 25 mol % or higher.

It is also preferable that the resin having a polymerizable group further includes a repeating unit having an acid group at a side chain. In this aspect, a pixel having higher rectangularity is likely to be formed. The content of the repeating unit having an acid group at a side chain is preferably 10 to 60 mol % with respect to all the repeating units of the resin. The upper limit is preferably 40 mol % or lower and more preferably 25 mol % or lower. The lower limit is preferably 10 mol % or higher and more preferably 20 mol % or higher.

It is also preferable that the resin used in the present invention includes a repeating unit derived from monomer components including a compound represented by the following Formula (ED1) and/or a compound represented by the following Formula (ED2) (hereinafter, these compounds will also be referred to as “ether dimer”) is also preferable.

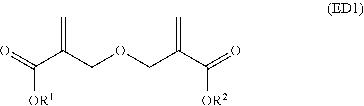

In Formula (ED1), R¹ and R² each independently represent a hydrogen atom or a hydrocarbon group having 1 to 25 carbon atoms which may have a substituent.

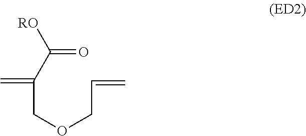

In Formula (ED2), R represents a hydrogen atom or an organic group having 1 to 30 carbon atoms. The details of Formula (ED2) can be found in JP2010-168539A, the content of which is incorporated herein by reference.

Specific examples of the ether dimer can be found in paragraph “0317” of JP2013-29760A, the content of which is incorporated herein by reference.

It is also preferable that the resin used in the present invention includes a repeating unit which is derived from a compound represented by the following Formula (X).

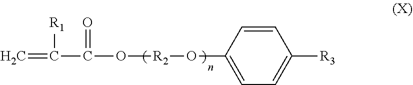

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may have a benzene ring. n represents an integer of 1 to 15.

Examples of the resin having an acid group and/or a polymerizable group include resins having the following structures. In the following structural formulae, Me represents a methyl group.

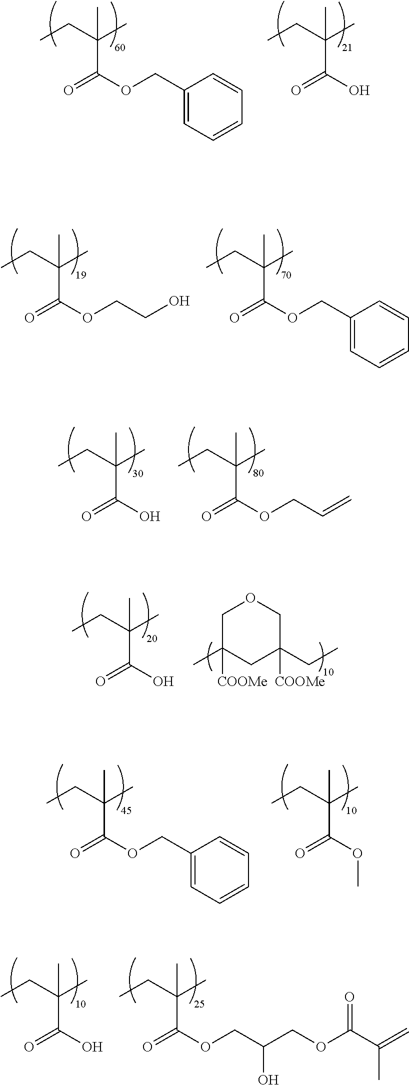

The photosensitive composition according to the embodiment of the present invention may include a resin as a dispersant. Examples of the dispersant include an acidic dispersant (acidic resin) and a basic dispersant (basic resin). Here, the acidic dispersant (acidic resin) refers to a resin in which the content of an acid group is more than the content of a basic group. In a case where the sum of the amount of an acid group and the amount of a basic group in the acidic dispersant (acidic resin) is represented by 100 mol %, the amount of the acid group in the acidic resin is preferably 70 mol % or higher and more preferably substantially 100 mol %. The acid group in the acidic dispersant (acidic resin) is preferably a carboxyl group. An acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) refers to a resin in which the amount of a basic group is more than the amount of an acid group. In a case where the sum of the amount of an acid group and the amount of a basic group in the basic dispersant (basic resin) is represented by 100 mol %, the amount of the basic group in the basic resin is preferably higher than 50 mol %. The basic group in the basic dispersant is preferably an amino group.

It is preferable that the resin used as the dispersant further includes a repeating unit having an acid group. In a case where the resin used as the dispersant further includes a repeating unit having an acid group, a photosensitive composition having excellent developability can be obtained, and the generation of development residues can be effectively suppressed during the formation of a pixel using a photolithography method.

It is preferable that the resin used as the dispersant is a graft copolymer. Since the graft copolymer has affinity to the solvent due to the graft chain, the pigment dispersibility and the dispersion stability overtime are excellent. The details of the graft copolymer can be found in the description of paragraphs “0025” to “0094” of JP2012-255128A, the content of which is incorporated herein by reference. In addition, specific examples of the graft copolymer include the following resins. The following resin may also be a resin having an acid group (alkali-soluble resin). In addition, other examples of the graft copolymer include resins described in paragraphs “0072” to “0094” of JP2012-255128A, the content of which is incorporated herein by reference.

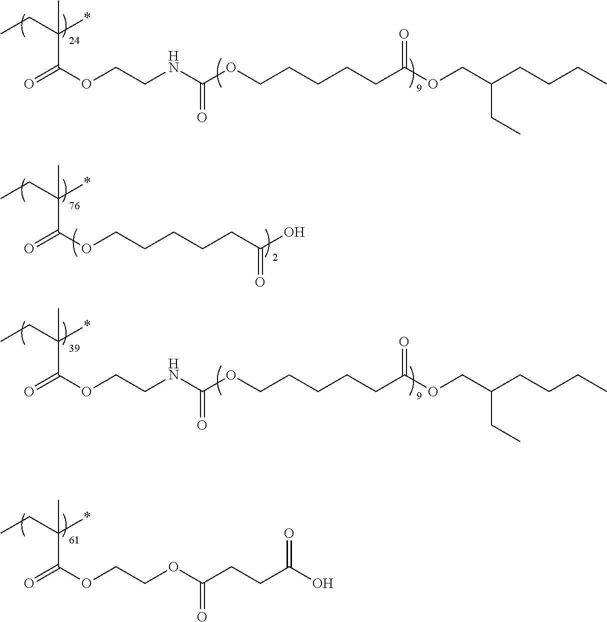

In addition, in the present invention, as the resin (dispersant), an oligoimine dispersant having a nitrogen atom at at least either a main chain or a side chain is also preferably used. As the oligoimine dispersant, a resin, which includes a structural unit having a partial structure X with a functional group (pKa: 14 or lower) and a side chain including a side chain Y having 40 to 10,000 atoms and has a basic nitrogen atom at at least either a main chain or a side chain, is preferable. The basic nitrogen atom is not particularly limited as long as it is a nitrogen atom exhibiting basicity. The oligoimine dispersant can be found in the description of paragraphs “0102” to “0166” of JP2012-255128A, the content of which is incorporated herein by reference. As the oligoimine dispersant, a resin having the following structure or a resin described in paragraphs “0168” to “0174” of JP2012-255128A can be used.

In addition, it is also preferable that the resin used as a dispersant is a resin that includes a repeating unit having an ethylenically unsaturated bond group at a side chain. The content of the repeating unit having an ethylenically unsaturated bond group at a side chain is preferably 10 mol % or higher, more preferably 10% to 80 mol %, and still more preferably 20% to 70 mol % with respect to all the repeating units of the resin.

The dispersant is available as a commercially available product, and specific examples thereof include Disperbyk-111 and 161 (manufactured by BYK Chemie). In addition, a pigment dispersant described in paragraphs “0041” to “0130” of JP2014-130338A can also be used, the content of which is incorporated herein by reference. In addition, the resin having an acid group or the like can also be used as a dispersant.

The content of the resin is preferably 5% to 25 mass % with respect to the total solid content of the photosensitive composition. From the viewpoint of film forming properties, the lower limit is preferably 7 mass % or higher, more preferably 9 mass % or higher, and still more preferably 11 mass % or higher. From the viewpoint of suitable liquid viscosity, the upper limit is preferably 22 mass % or lower, more preferably 19 mass % or lower, and still more preferably 16 mass % or lower.

In addition, the content of the resin having an acid group is preferably 3% to 23 mass % with respect to the total solid content of the photosensitive composition. From the viewpoint of developability, the lower limit is preferably 4 mass % or higher, more preferably 6 mass % or higher, and still more preferably 8 mass % or higher. From the viewpoint of developer resistance of the film, the upper limit is preferably 21 mass % or lower, more preferably 18 mass % or lower, and still more preferably 15 mass % or lower.

In addition, from the viewpoint of developability, the content of the resin having an acid group is preferably 50 mass % or higher, more preferably 70 mass % or higher, and still more preferably 80 mass % or higher with respect to the total content of the resin having an acid group. The upper limit may be 100 mass % or lower, 95 mass % or lower, or 90 mass % or lower.

In addition, the total content of the polymerizable monomer and the resin is preferably 10% to 40 mass % with respect to the total solid content of the photosensitive composition. From the viewpoint of curing properties, the lower limit is preferably 13 mass % or higher, more preferably 16 mass % or higher, and still more preferably 19 mass % or higher. From the viewpoint of suitable liquid viscosity, the upper limit is preferably 37 mass % or lower, more preferably 34 mass % or lower, and still more preferably 31 mass % or lower. In addition, the content of the resin is preferably 25 to 400 parts by mass with respect to 100 parts by mass of the polymerizable monomer. From the viewpoint of simultaneously achieving curing properties and developability, the lower limit is preferably 50 parts by mass or more and more preferably 75 parts by mass. From the viewpoint of suitable liquid viscosity, the upper limit is preferably 300 parts by mass or less and more preferably 200 parts by mass or less.

### Silane Coupling Agent

The photosensitive composition according to the embodiment of the present invention may include a silane coupling agent. In this aspect, the adhesiveness of the obtained film with the support can be improved. In the present invention, the silane coupling agent refers to a silane compound having a functional group other than a hydrolyzable group. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group. Among these, an alkoxy group is preferable. That is, it is preferable that the silane coupling agent is a compound having an alkoxysilyl group. Examples of the functional group other than a hydrolyzable group include a vinyl group, a (meth)allyl group, a (meth)acryloyl group, a mercapto group, an epoxy group, an oxetanyl group, an amino group, an ureido group, a sulfide group, an isocyanate group, and a phenyl group. Among these, an amino group, a (meth)acryloyl group, or an epoxy group is preferable. Specific examples of the silane coupling agent include a compound described in paragraphs “0018” to “0036” of JP2009-288703A and a compound described in paragraphs “0056” to “0066” of JP2009-242604A, the contents of which are incorporated herein by reference.

The content of the silane coupling agent is preferably 0.1% to 5 mass % with respect to the total solid content of the photosensitive composition. The upper limit is preferably 3 mass % or lower, and more preferably 2 mass % or lower. The lower limit is preferably 0.5 mass % or higher and more preferably 1 mass % or higher. As the silane coupling agent, one kind may be used alone, or two or more kinds may be used. In a case where two or more silane coupling agents are used in combination, it is preferable that the total content of the two or more silane coupling agents is in the above-described range.

### Pigment Derivative

The photosensitive composition according to the embodiment of the present invention may further include a pigment derivative. Examples of the pigment derivative include a compound having a structure in which a portion of a pigment is substituted with an acid group, a basic group, a group having a salt structure, or a phthalimidomethyl group. As the pigment derivative, a compound represented by Formula (B1) is preferable.

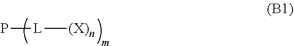

In Formula (B1), P represents a colorant structure, L represents a single bond or a linking group, X represents an acid group, a basic group, a group having a salt structure, or a phthalimidomethyl group, m represents an integer of 1 or more, n represents an integer of 1 or more, in a case where m represents 2 or more, a plurality of L's and a plurality of X's may be different from each other, and in a case where n represents 2 or more, a plurality of X's may be different from each other.

In Formula (B1), the colorant structure represented by P is preferably at least one selected from a pyrrolopyrrole colorant structure, a diketo pyrrolopyrrole colorant structure, a quinacridone colorant structure, an anthraquinone colorant structure, a dianthraquinone colorant structure, a benzoisoindole colorant structure, a thiazine indigo colorant structure, an azo colorant structure, a quinophthalone colorant structure, a phthalocyanine colorant structure, a naphthalocyanine colorant structure, a dioxazine colorant structure, a perylene colorant structure, a perinone colorant structure, a benzimidazolone colorant structure, a benzothiazole colorant structure, a benzimidazole colorant structure, and a benzoxazole colorant structure, and more preferably at least one selected from a pyrrolopyrrole colorant structure, a diketo pyrrolo pyrrolopyrrole colorant structure, a quinacridone colorant structure, or a benzimidazolone colorant structure.

Examples of the linking group represented by L include a hydrocarbon group, a heterocyclic group, —NR—, —SO₂—, —S—, —O—, —CO—, and a group consisting of a combination thereof. R represents a hydrogen atom, an alkyl group, or an aryl group.

Examples of the acid group represented by X include a carboxyl group, a sulfo group, a carboxylic acid amide group, a sulfonic acid amide group, and an imide acid group. As the carboxylic acid amide group, a group represented by —NHCOR^{X1} is preferable. As the sulfonic acid amide group, a group represented by —NHSO₂R^{X2} is preferable. As the imide acid group, a group represented by —SO₂NHSO₂R^{X3}, —CONHSO₂R^{X4}, —CONHCOR^{X5}, or —SO₂NHCOR^{X6} is preferable. R^{X1} to R^{X6} each independently represent a hydrocarbon group or a heterocyclic group. The hydrocarbon group and the heterocyclic group represented by R^{X1} to R^{X6} may further have a substituent. As the substituent which may be further included, a halogen atom is preferable, and a fluorine atom is more preferable. Examples of the basic group represented by X include an amino group. Examples of the salt structure represented by X include a salt of the acid group or the basic group described above.

Examples of the pigment derivative include compounds having the following structures. In addition, for example, compounds described in JP1981-118462A (JP-S56-118462A), JP1988-264674A (JP-S63-264674A), JP1989-217077A (JP-H1-217077A), JP1991-009961A (JP-H3-009961A), JP1991-026767A (JP-H3-026767A), JP1991-153780A (JP-H3-153780A), JP1991-045662A (JP-H3-045662A), JP1992-285669A (JP-H4-285669A), JP1994-145546A (JP-H6-145546A), JP1994-212088A (JP-H6-212088A), JP1994-240158A (JP-H6-240158A), JP1998-030063A (JP-H10-030063A), JP1998-195326A (JP-H10-195326A), paragraphs “0086” to “0098” of WO2011/024896A, paragraphs “0063” to “0094” of WO2012/102399A, and paragraph “0082” of WO2017/038252A can be used, the content of which is incorporated herein by reference.

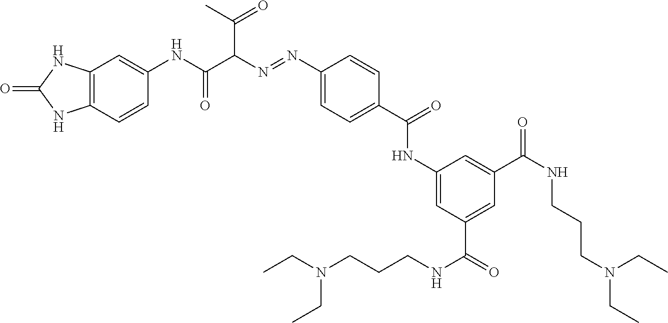 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

The content of the pigment derivative is preferably 1 to 50 parts by mass with respect to 100 parts by mass of the pigment. The lower limit value is preferably 3 parts by mass or more and more preferably 5 parts by mass or more. The upper limit value is preferably 40 parts by mass or less and more preferably 30 parts by mass or less. In a case where the content of the pigment derivative is in the above-described range, the pigment dispersibility can be improved, and aggregation of the pigment can be efficiently suppressed. As the pigment derivative, one kind may be used alone, or two or more kinds may be used in combination. In a case where two or more pigment derivatives are used in combination, it is preferable that the total content of the two or more pigment derivatives is in the above-described range.

### Solvent

The photosensitive composition according to the embodiment of the present invention may include a solvent. Examples of the solvent include an organic solvent. Basically, the solvent is not particularly limited as long as it satisfies the solubility of the respective components and the application properties of the composition. Examples of the organic solvent include esters, ethers, ketones, and aromatic hydrocarbons. The details of the organic solvent can be found in paragraph “0223” of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, and propylene glycol monomethyl ether acetate. In the present invention, as the organic solvent, one kind may be used alone, or two or more kinds may be used in combination. In addition, 3-methoxy-N,N-dimethylpropanamide or 3-butoxy-N,N-dimethylpropanamide is also preferable from the viewpoint of improving solubility. In this case, it may be preferable that the content of the aromatic hydrocarbon (for example, benzene, toluene, xylene, or ethylbenzene) as the solvent is low (for example, 50 mass parts per million (ppm) or lower, 10 mass ppm or lower, or 1 mass ppm or lower with respect to the total mass of the organic solvent) in consideration of environmental aspects and the like.

In the present invention, a solvent having a low metal content is preferably used. For example, the metal content in the solvent is preferably 10 mass parts per billion (ppb) or lower. Optionally, a solvent having a metal content at a mass parts per trillion (ppt) level may be used. For example, such a high-purity solvent is available from Toyo Gosei Co., Ltd. (The Chemical Daily, Nov. 13, 2015).

Examples of a method of removing impurities such as metal from the solvent include distillation (for example, molecular distillation or thin-film distillation) and filtering using a filter. The pore size of a filter used for the filtering is preferably 10 μm or less, more preferably m or less, and still more preferably 3 μm or less. As a material of the filter, polytetrafluoroethylene, polyethylene, or nylon is preferable.

The solvent may include an isomer (a compound having the same number of atoms and a different structure). In addition, the organic solvent may include only one isomer or a plurality of isomers.

In the present invention, as the organic solvent, an organic solvent containing 0.8 mmol/L or lower of a peroxide is preferable, and an organic solvent containing substantially no peroxide is more preferable.

The content of the solvent in the photosensitive composition is preferably 10% to 95 mass %, more preferably 20% to 90 mass %, and still more preferably 30% to 90 mass %.

In addition, it is preferable that the photosensitive composition according to the embodiment of the present invention does not substantially include an environmentally regulated material from the viewpoint of environmental regulations. In the present invention, not substantially including the environmentally regulated material represents that the content of the environmentally regulated material in the photosensitive composition is 50 mass ppm or lower, preferably 30 mass ppm or lower, more preferably 10 mass ppm or lower, and still more preferably 1 mass ppm or lower. Examples of the environmentally regulated material include: benzene; an alkylbenzene such as toluene or xylene; and a halogenated benzene such as chlorobenzene. These compounds are registered as environmentally regulated materials based on Registration Evaluation Authorization and Restriction of Chemicals (REACH) regulation, Pollutant Release and Transfer Register (PRTR) method, Volatile Organic Compounds (VOC) regulation, and the like, and the amount thereof used and a handling method thereof are strictly regulated. These compounds are used as solvents in a case where each of the components or the like used in the photosensitive composition according to the embodiment of the present invention is manufactured, and may be incorporated into the photosensitive composition as residual solvents. From the viewpoints of safety for humans and consideration of the environment, it is preferable that these materials are reduced as much as possible. Examples of a method of reducing the environmentally regulated material include a method of distilling off the environmentally regulated material from the system by heating or depressurizing the system such that the temperature of the system is higher than or equal to a boiling point of the environmentally regulated material. In addition, in a case where a small amount of environmentally regulated material is removed by distillation, a method of azeotroping the environmentally regulated material with a solvent having the same boiling point as that of the corresponding solvent is also useful to increase the efficiency. In addition, in a case where a radically polymerizable compound is included, in order to suppress intermolecular crosslinking caused by the progress of a radical polymerization reaction during distillation under reduced pressure, a polymerization inhibitor or the like may be added for distillation under reduced pressure. This distillation method can be performed in, for example, any of a step of raw materials, a step of a reaction product (for example, a resin solution or a polyfunctional monomer solution after polymerization) obtained from a reaction of the raw materials, or a step of a composition prepared by mixing these compounds with each other.

### Polymerization Inhibitor

The photosensitive composition according to the embodiment of the present invention may include a polymerization inhibitor. Examples of the polymerization inhibitor include hydroquinone, p-methoxyphenol, di-tert-butyl-p-cresol, pyrogallol, t-butylcatechol, benzoquinone, 4,4′-thiobis(3-methyl-6-tert-butylphenol), 2,2′-methylenebis(4-methyl-6-t-butylphenol), and N-nitrosophenylhydroxyamine salt (for example, an ammonium salt or a cerium (III) salt). Among these, p-methoxyphenol is preferable. The content of the polymerization inhibitor is preferably 0.001% to 5 mass % with respect to the total solid content of the photosensitive composition.

### Surfactant

The photosensitive composition according to the embodiment of the present invention may include a surfactant. As the surfactants, various surfactants such as a fluorine surfactant, a nonionic surfactant, a cationic surfactant, an anionic surfactant, or a silicone surfactant can be used. The details of the surfactant can be found in paragraphs “0238” to “0245” of WO2015/166779A, the content of which is incorporated herein by reference.

In the present invention, it is preferable that the surfactant is a fluorine surfactant. By the photosensitive composition containing a fluorine surfactant, liquid characteristics (in particular, fluidity) are further improved, and liquid saving properties can be further improved. In addition, a film having reduced thickness unevenness can be formed.

The fluorine content in the fluorine surfactant is preferably 3% to 40 mass %, more preferably 5% to 30 mass %, and still more preferably 7% to 25 mass %. The fluorine surfactant in which the fluorine content is in the above-described range is effective from the viewpoints of the uniformity in the thickness of the coating film and liquid saving properties, and the solubility thereof in the composition is also excellent.

Examples of the fluorine surfactant include a surfactant described in paragraphs “0060” to “0064” of JP2014-041318A (paragraphs “0060” to “0064” of corresponding WO2014/017669A) and a surfactant described in paragraphs “0117” to “0132” of JP2011-132503A, the contents of which are incorporated herein by reference. Examples of a commercially available product of the fluorine surfactant include: MEGAFACE F171, F172, F173, F176, F177, F141, F142, F143, F144, R³⁰, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by AGC Inc.); and POLYFOX PF636, PF656, PF6320, PF6520, and PF7002 (all of which are manufactured by OMNOVA Solutions Inc.).

In addition, as the fluorine surfactant, an acrylic compound having a molecular structure which has a functional group having a fluorine atom and in which the functional group having a fluorine atom is cut and a fluorine atom is volatilized during heat application can also be preferably used. Examples of the fluorine surfactant include MEGAFACE DS series (manufactured by DIC Corporation, The Chemical Daily, Feb. 22, 2016, Nikkei Business Daily, Feb. 23, 2016), for example, MEGAFACE DS-21.

In addition, as the fluorine surfactant, a polymer of a fluorine-containing vinyl ether compound having a fluorinated alkyl group or a fluorinated alkylene ether group and a hydrophilic vinyl ether compound is also preferable. The details of this fluorine surfactant can be found in JP2016-216602A, the content of which is incorporated herein by reference.

As the fluorine surfactant, a block polymer can also be used. Examples of the block polymer include a compound described in JP2011-089090A. As the fluorine surfactant, a fluorine-containing polymer compound can be preferably used, the fluorine-containing polymer compound including: a repeating unit derived from a (meth)acrylate compound having a fluorine atom; and a repeating unit derived from a (meth)acrylate compound having 2 or more (preferably 5 or more) alkyleneoxy groups (preferably an ethyleneoxy group and a propyleneoxy group). For example, the following compound can also be used as the fluorine surfactant used in the present invention.

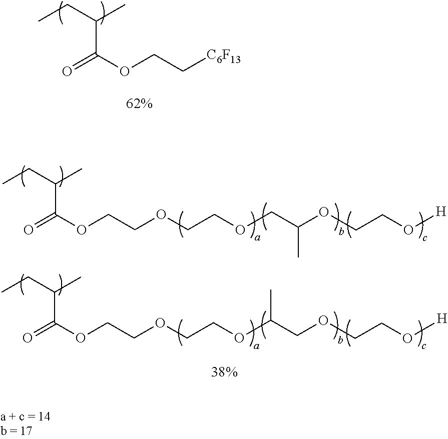

The weight-average molecular weight of the compound is preferably 3,000 to 50,000 and, for example, 14,000. In the compound, “%” representing the proportion of a repeating unit is mol %.

In addition, as the fluorine surfactant, a fluorine-containing polymer having an ethylenically unsaturated bond group at a side chain can also be used. Specific examples include a compound described in paragraphs “0050” to “0090” and paragraphs “0289” to “0295” of JP2010-164965A, for example, MEGAFACE RS-101, RS-102, RS-718K, and RS-72-K manufactured by DIC Corporation. As the fluorine surfactant, a compound described in paragraphs “0015” to “0158” of JP2015-117327A can also be used.

Examples of the nonionic surfactant include glycerol, trimethylolpropane, trimethylolethane, an ethoxylate and a propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF SE), TETRONIC 304, 701, 704, 901, 904, and 150R1 (manufactured by BASF SE)), SOLSPERSE 20000 (manufactured by Lubrication Technology Inc.), NCW-101, NCW-1001, and NCW-1002 (all of which are manufactured by Wako Pure Chemical Industries, Ltd.), PIONIN D-6112, D-6112-W, and D-6315 (all of which are manufactured by Takemoto Oil&Fat Co., Ltd.), and OLFINE E1010, SURFYNOL 104, 400, and 440 (all of which are manufactured by Nissin Chemical Co., Ltd.).

Examples of the silicone surfactant include: TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Corporation); TSF-4440, TSF-4300, TSF-4445, TSF-4460, and TSF-4452 (all of which are manufactured by Momentive Performance Materials Inc.); KP-341, KF-6001, and KF-6002 (all of which are manufactured by Shin-Etsu Chemical Co., Ltd.); and BYK307, BYK323, and BYK330 (all of which are manufactured by BYK-Chemie Japan K.K.). In addition, as the silicon surfactant, a compound having the following structure can also be used.

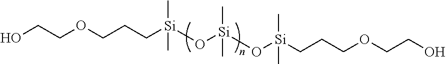

The content of the surfactant is preferably 0.001 mass % to 5.0 mass % and more preferably 0.005% to 3.0 mass % with respect to the total solid content of the photosensitive composition. As the surfactant, one kind may be used alone, or two or more kinds may be used. In a case where two or more surfactants are used in combination, it is preferable that the total content of the two or more surfactants is in the above-described range.

### Ultraviolet Absorber

The photosensitive composition according to the embodiment of the present invention may include an ultraviolet absorber. As the ultraviolet absorber, a conjugated diene compound, an amino diene compound, a salicylate compound, a benzophenone compound, a benzotriazole compound, an acrylonitrile compound, a hydroxyphenyltriazine compound an indole compound, or a triazine compound can be used. The details of the ultraviolet absorber can be found in paragraphs “0052” to “0072” of JP2012-208374A, paragraphs “0317” to “0334” of JP2013-068814A, and paragraphs “0061” to “0080” of JP2016-162946A, the contents of which are incorporated herein by reference. Specific examples of the ultraviolet absorber include compounds having the following structures. Examples of a commercially available product of the ultraviolet absorber include UV-503 (manufactured by Daito Chemical Co., Ltd.). In addition, examples of the benzotriazole compound include MYUA series (manufactured by Miyoshi Oil&Fat Co., Ltd.; The Chemical Daily, Feb. 1, 2016).

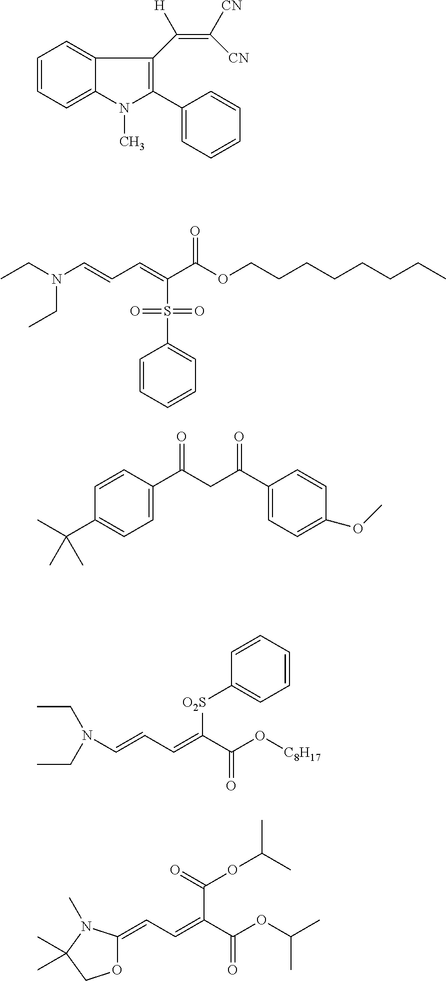

The content of the ultraviolet absorber is preferably 0.01% to 10 mass % and more preferably 0.01% to 5 mass % with respect to the total solid content of the photosensitive composition. In the present invention, as the ultraviolet absorber, one kind may be used alone, or two or more kinds may be used. In a case where two or more ultraviolet absorbers are used in combination, it is preferable that the total content of the two or more ultraviolet absorbers is in the above-described range.

### Antioxidant

The photosensitive composition according to the embodiment of the present invention may include an antioxidant. Examples of the antioxidant include a phenol compound, a phosphite compound, and a thioether compound. As the phenol compound, any phenol compound which is known as a phenol antioxidant can be used. Preferable examples of the phenol compound include a hindered phenol compound. A compound having a substituent at a position (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite group in the same molecule is also preferable. In addition, as the antioxidant, a phosphorus antioxidant can also be preferably used. Examples of the phosphorus antioxidant include tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl)phosphite. Examples of the commercially available product of the antioxidant include ADEKA STAB AO-20, ADEKA STAB AO-30, ADEKA STAB AO-40, ADEKA STAB AO-50, ADEKA STAB AO-50F, ADEKA STAB AO-60, ADEKA STAB AO-60G, ADEKA STAB AO-80, and ADEKA STAB AO-330 (all of which are manufactured by Adeka Corporation).

The content of the antioxidant is preferably 0.01% to 20 mass % and more preferably 0.3% to 15 mass % with respect to the total solid content of the photosensitive composition. As the antioxidant, one kind may be used alone, or two or more kinds may be used in combination. In a case where two or more antioxidants are used in combination, it is preferable that the total content of the two or more antioxidants is in the above-described range.

### Other Components

Optionally, the photosensitive composition according to the embodiment of the present invention may further include a sensitizer, a curing accelerator, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By the composition appropriately including the components, properties such as film properties can be adjusted. The details of the components can be found in, for example, paragraph “0183” of JP2012-003225A (corresponding to paragraph “0237” of US2013/0034812A) and paragraphs “0101” to “0104” and “0107” to “0109” of JP2008-250074A, the contents of which are incorporated herein by reference. In addition, the photosensitive composition according to the embodiment of the present invention may optionally include a potential antioxidant. The potential antioxidant is a compound in which a portion that functions as the antioxidant is protected by a protective group and this protective group is desorbed by heating the compound at 100° C. to 250° C. or by heating the compound at 80° C. to 200° C. in the presence of an acid or abase catalyst. Examples of the potential antioxidant include a compound described in WO2014/021023A, WO2017/030005A, and JP2017-008219A. Examples of a commercially available product of the potential antioxidant include ADEKA ARKLS GPA-5001 (manufactured by Adeka Corporation).

For example, in a case where a film is formed by coating, the viscosity (23° C.) of the photosensitive composition according to the embodiment of the present invention is preferably 1 to 100 mPa·s. The lower limit is more preferably 2 mPa·s or higher and still more preferably 3 mPa·s or higher. The upper limit is preferably 50 mPa·s or lower, more preferably 30 mPa·s or lower, and still more preferably 15 mPa·s or lower.

### <Storage Container>

A storage container of the photosensitive composition according to the embodiment of the present invention is not particularly limited, and a well-known storage container can be used. In addition, as the storage container, in order to suppress infiltration of impurities into the raw materials or the composition, a multilayer bottle in which a container inner wall having a six-layer structure is formed of six kinds of resins or a bottle in which a container inner wall having a seven-layer structure is formed of six kinds of resins is preferably used. Examples of the container include a container described in JP2015-123351A.

### <Method of Preparing Photosensitive Composition>

The photosensitive composition according to the embodiment of the present invention can be prepared by mixing the above-described components with each other. During the preparation of the photosensitive composition, all the components may be dissolved or dispersed in a solvent at the same time to prepare the photosensitive composition. Optionally, two or more solutions or dispersion liquids to which the respective components are appropriately added may be prepared, and the solutions or dispersion liquids may be mixed with each other during use (during application) to prepare the photosensitive composition.

In addition, in a case where the photosensitive composition according to the embodiment of the present invention includes particles of a pigment or the like, it is preferable that a process of dispersing the particles is provided. Examples of a mechanical force used for dispersing the particles in the process of dispersing the particles include compression, squeezing, impact, shearing, and cavitation. Specific examples of the process include a beads mill, a sand mill, a roll mill, a ball mill, a paint shaker, a Microfluidizer, a high-speed impeller, a sand grinder, a flow jet mixer, high-pressure wet atomization, and ultrasonic dispersion. During the pulverization of the particles using a sand mill (beads mill), it is preferable that the process is performed under conditions for increasing the pulverization efficiency, for example, by using beads having a small size and increasing the filling rate of the beads. In addition, it is preferable that coarse particles are removed by filtering, centrifugal separation, and the like after pulverization. In addition, as the process and the disperser for dispersing the particles, a process and a disperser described in “Complete Works of Dispersion Technology, Johokiko Co., Ltd., Jul. 15, 2005”, “Dispersion Technique focusing on Suspension (Solid/Liquid Dispersion) and Practical Industrial Application, Comprehensive Reference List, Publishing Department of Management Development Center, Oct. 10, 1978”, and paragraph “0022” JP2015-157893A can be suitably used. In addition, in the process of dispersing the particles, particles may be refined in a salt milling step. A material, a device, process conditions, and the like used in the salt milling step can be found in, for example, JP2015-194521A and JP2012-046629A.

During the preparation of the photosensitive composition according to the embodiment of the present invention, it is preferable that the photosensitive composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable. The pore size of the filter is suitably about 0.01 to 7.0 μm and is preferably about 0.01 to 3.0 μm and more preferably about 0.05 to 0.5 μm. In a case where the pore size of the filter is in the above-described range, fine foreign matter can be reliably removed. In addition, it is preferable that a fibrous filter material is used. Examples of the fibrous filter material include polypropylene fiber, nylon fiber, and glass fiber. Specific examples include a filter cartridge of SBP type series (for example, SBP008), TPR type series (for example, TPR002 or TPR005), and SHPX type series (for example, SHPX003) all of which are manufactured by Roki Techno Co., Ltd. In a case where a filter is used, a combination of different filters (for example, a first filter and a second filter) may be used. At this time, the filtering using each of the filters may be performed once, or twice or more. In addition, a combination of filters having different pore sizes in the above-described range may be used. In addition, the filtering using the first filter may be performed only on the dispersion liquid, and the filtering using the second filter may be performed on a mixture of the dispersion liquid and other components.

### <Method of Manufacturing Optical Filter>

Next, a method of manufacturing an optical filter using the photosensitive composition according to the embodiment of the present invention will be described. Examples of the kind of the optical filter include a color filter and an infrared transmitting filter.

It is preferable that the method of manufacturing an optical filter according to an embodiment of the present invention includes: a step (photosensitive composition layer forming step) of applying the above-described photosensitive composition according to the embodiment of the present invention to a support to form a photosensitive composition layer; a step (exposure step) of irradiating the photosensitive composition layer with light having a wavelength of 300 nm or shorter to be exposed in a pattern shape; and a step (development step) of forming a pixel by removing a non-exposed portion of the photosensitive composition layer by development. Hereinafter, the respective steps will be described.

### (Photosensitive Composition Layer Forming Step)

In the photosensitive composition layer forming step, the above-described photosensitive composition according to the embodiment of the present invention is applied to a support to form a photosensitive composition layer. Examples of the support include a substrate formed of a material such as silicon, non-alkali glass, soda glass, PYREX (registered trade name) glass, or quartz glass. In addition, for example, an InGaAs substrate is preferably used. In addition, a charge coupled device (CCD), a complementary metal-oxide semiconductor (CMOS), a transparent conductive film, or the like may be formed on the support. In addition, a black matrix that separates pixels from each other may be formed on the support. In addition, optionally, an undercoat layer may be provided on the support to improve adhesiveness with a layer above the support, to prevent diffusion of materials, or to make a surface of the substrate flat.

As a method of applying the photosensitive composition to the support, a well-known method can be used. Examples of the well-known method include: a drop casting method; a slit coating method; a spray coating method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprint lithography method. The application method using an ink jet method is not particularly limited, and examples thereof include a method (in particular, pp. 115 to 133) described in “Extension of Use of Ink Jet—Infinite Possibilities in Patent—” (February, 2005, S.B. Research Co., Ltd.) and methods described in JP2003-262716A, JP2003-185831A, JP2003-261827A, JP2012-126830A, and JP2006-169325A. In addition, as the method of applying the photosensitive composition, methods described in WO2017/030174A and WO2017/018419A can also be used, the contents of which are incorporated herein by reference.

The photosensitive composition may be dried (pre-baked) after being applied to the support. In a case where pre-baking is performed, the pre-baking temperature is preferably 150° C. or lower, more preferably 120° C. or lower, and still more preferably 110° C. or lower. The lower limit is, for example, 50° C. or higher or 80° C. or higher. The pre-baking time is preferably 10 to 3000 seconds, more preferably 40 to 2500 seconds, and still more preferably 80 to 2200 seconds. Drying can be performed using a hot plate, an oven, or the like.

### (Exposure Step)

Next, the photosensitive composition layer formed on the support as described above is irradiated with light having a wavelength of 300 nm or shorter to be exposed in a pattern shape. By exposing the photosensitive composition layer through a mask having a predetermined mask pattern, the photosensitive composition layer can be exposed in a pattern shape. As a result, the exposed portion of the photosensitive composition layer can be cured.

The light used for the exposure is not particularly limited as long as it is light having a wavelength of 300 nm or shorter, and is preferably light having a wavelength of 270 nm or shorter and more preferably light having a wavelength of 250 nm or shorter. In addition, the above-described light is preferably light having a wavelength of 180 nm or longer. Specific examples of the light include a KrF ray (wavelength: 248 nm) and an ArF ray (wavelength: 193 nm). Among these, for example, a KrF ray (wavelength: 248 nm) is preferable from the viewpoint that a bond to the coloring material or the like in the photosensitive composition is not likely to be cut. In addition, it is preferable that the exposure is performed using a KrF scanner exposure device. In this aspect, the alignment accuracy of exposure is excellent, and a fine pixel is likely to be formed. Examples of the light source include an excimer laser light source and a far ultraviolet lamp. From the viewpoint that the composition can be instantaneously exposed to high-intensity light and curing properties are excellent, an excimer laser light source is preferable.

In addition, during the exposure the composition may be continuously irradiated with and exposed to light having a wavelength of 300 nm or shorter or may be irradiated with and exposed to pulses of the light. From the viewpoint that higher curing properties can be easily obtained, it is preferable that the composition is irradiated with and exposed (pulse exposure) to pulses of the light. The pulse exposure refers to an exposure method in which light irradiation and rest are repeated in a cycle of a short period of time (for example, a level of milliseconds). In the case of the pulse exposure, from the viewpoint of instantaneously generating a large amount of an active species such as a radical easily, the pulse duration is preferably 100 nanoseconds (ns) or shorter, more preferably 50 nanoseconds or shorter, and still more preferably 30 nanoseconds or shorter. The lower limit of the pulse duration is not particularly limited and may be 1 femtoseconds (fs) or longer or 10 femtoseconds (fs) or longer. From the viewpoint of easily promoting thermal polymerization caused by exposure heat, the frequency is preferably 1 kHz or higher, more preferably 2 kHz or higher, and still more preferably 4 kHz or higher. From the viewpoint of easily suppressing deformation of a substrate or the like caused by exposure heat, the upper limit of the frequency is preferably 50 kHz or lower, more preferably 20 kHz or lower, and still more preferably 10 kHz or lower. From the viewpoint of curing properties, the maximum instantaneous illuminance is preferably 50000000 W/m² or higher, more preferably 100000000 W/m² or higher, and still more preferably 200000000 W/m² or higher. In addition, from the viewpoint of high illuminance reciprocity failure, the upper limit of the maximum instantaneous illuminance is preferably 1000000000 W/m² or lower, more preferably 800000000 W/m² or lower, and still more preferably 500000000 W/m² or lower. The pulse duration refers to the time during which light is irradiated during a pulse period. In addition, the frequency refers to the number of pulse periods per second. In addition, the maximum instantaneous illuminance refers to an average illuminance within a time during which light is irradiated in a pulse period. In addition, the pulse period refers to a period in which light irradiation and rest during pulse exposure are set as one cycle.

For example, the exposure dose is preferably 1 to 2000 mJ/cm². The upper limit is preferably 1000 mJ/cm² or lower and more preferably 500 mJ/cm² or lower. The lower limit is preferably 5 mJ/cm² or higher, more preferably 10 mJ/cm² or higher, and still more preferably 20 mJ/cm² or higher. In addition, in the case of pulse exposure, the exposure dose is preferably 15 to 300 mJ/cm². The upper limit is preferably 250 mJ/cm² or lower and more preferably 150 mJ/cm² or lower. The lower limit is preferably 25 mJ/cm² or higher, more preferably 35 mJ/cm² or higher, and still more preferably 45 mJ/cm² or higher.

The oxygen concentration during exposure can be appropriately selected. The exposure may be performed not only in the air but also in a low-oxygen atmosphere having an oxygen concentration of 19 vol % or lower (for example, 15 vol %, 5 vol %, or substantially 0 vol %) or in a high-oxygen atmosphere having an oxygen concentration of higher than 21 vol % (for example, 22 vol %, 30 vol %, or 50 vol %).

### (Development Step)

Next, after the exposure step, a pixel (pattern) is formed by removing a non-exposed portion of the photosensitive composition layer by development. The non-exposed portion of the photosensitive composition layer can be removed by development using a developer. As a result, the non-exposed portion of the photosensitive composition layer in the exposure step is eluted into the developer, and only the portion that is photocured in the above-described exposure step remains on the support. For example, the temperature of the developer is preferably 20° C. to 30° C. The development time is preferably 20 to 180 seconds. In addition, in order to further improve residue removing properties, a step of shaking the developer off per 60 seconds and supplying a new developer may be repeated multiple times.

As the developer, an alkaline aqueous solution in which the above alkaline agent is diluted with pure water is preferable. Examples of the alkaline agent include: an organic alkaline compound such as ammonia, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethyl bis(2-hydroxyethyl)ammonium hydroxide, choline, pyrrole, piperidine, or 1,8-diazabicyclo[5.4.0]-7-undecene; and an inorganic alkaline compound such as sodium hydroxide, potassium hydroxide, sodium carbonate, sodium bicarbonate, sodium silicate, or sodium metasilicate. From the viewpoints of environment and safety, it is preferable that the alkaline agent is a compound having a high molecular weight. A concentration of the alkaline agent in the alkaline aqueous solution is preferably 0.001% to 10 mass % and more preferably 0.01% to 1 mass %. In addition, the developer may further include a surfactant. Examples of the surfactant include the above-described surfactants. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution factor is not particularly limited and, for example, can be set to be in a range of 1.5 to 100 times. In a case where the alkaline aqueous solution is used as the developer, it is preferable that the layer is rinsed with pure water after development.

After the development and drying, an additional exposure treatment or a heating treatment (post-baking) can also be performed. The additional exposure treatment or the post-baking is a treatment which is performed after development to completely cure the film. In a case where the additional exposure treatment is performed, as light used for the exposure, for example, a g-ray, a h-ray, or an i-ray is preferable, and an i-ray is more preferable. In addition, a combination of the above-described rays may be used.

It is preferable that the thickness of the pixel (pattern) to be formed is appropriately selected depending on the kind of the pixel. For example, the thickness of the pixel is preferably 2.0 μm or less, more preferably 1.0 μm or less, and still more preferably 0.3 to 1.0 m. The upper limit is preferably 0.8 μm or less and more preferably 0.6 μm or less. The lower limit value is preferably 0.4 μm or more.

In addition, it is preferable that the size (line width) of the pixel (pattern) to be formed is selected depending on the use or the kind of the pixel. For example, the size of the pixel is preferably 2.0 μm or less. The upper limit is preferably 1.0 μm or less and more preferably 0.9 μm or less. The lower limit value is preferably 0.4 μm or more.

In a case where an optical filter including plural kinds of pixels is manufactured, at least one kind of pixel may be formed through the above-described steps, and it is preferable that a pixel to be initially formed (the first kind of pixel) is formed through the above-described steps.

A pixel to be secondly or subsequently formed (the second or subsequent kind of pixel) may be formed through the above-described steps or may be formed by exposure using light (for example, an i-ray) having a wavelength of longer than 300 nm.

### EXAMPLES

Hereinafter, the present invention will be described in detail using examples. Materials, used amounts, ratios, treatment details, treatment procedures, and the like shown in the following examples can be appropriately changed within a range not departing from the scope of the present invention. Accordingly, the scope of the present invention is not limited to the following specific examples.

### <Measurement of Weight-Average Molecular Weight (Mw) of Resin>

The weight-average molecular weight of the resin can be measured under the following conditions by gel permeation chromatography (GPC).

Kind of column: a column in which TOSOH TSK gel Super HZM-H, TOSOH TSK gel Super HZ4000, and TOSOH TSK gel Super HZ2000 were linked to each other
Developing solvent: tetrahydrofuran
Column temperature: 40° C.
Flow rate (sample injection volume): 1.0 μL (sample concentration: 0.1 mass %)
Device name: HLC-8220 GPC (manufactured by Tosoh Corporation)
Detector: refractive index (RI) detector
Calibration curve base resin: a polystyrene resin

### <Preparation of Photosensitive Composition>

The following raw materials were mixed, and the obtained mixture was filtered through a nylon filter (manufactured by Pall Corporation) having a pore size of 0.45 μm. This way, photosensitive compositions (compositions 1 to 25) having a concentration of solid contents of 20 mass % were prepared. The concentration of solid contents of each of the photosensitive compositions was adjusted by changing the mixing amount of propylene glycol monomethyl ether acetate (PGMEA).

TABLE 1

| | Pigment | | | | | | | | | | |
|---|---|---|---|---|---|---|---|---|---|---|---|
| | Dispersion | | | | | | Polymerizable | | Polymerizable | | |
| | Liquid | | Resin 1 | | Resin 2 | | Monomer 1 | | Monomer 2 | | |
| | | Mixing | | Mixing | | Mixing | | Mixing | | Mixing | |
| | | Amount | | Amount | | Amount | | Amount | | Amount | Photo- |
| | | (Part(s) | | (Part(s) | | (Part(s) | | (Part(s) | | (Part(s) | polymerization |
| | | by | | by | | by | | by | | by | Initiator 1 |
| | Kind | Mass) | Kind | Mass) | Kind | Mass) | Kind | Mass) | Kind | Mass) | Kind |
| Composition | A1 | 530 | B1 | 3 | | | M1 | 5 | M2 | 5 | I1 |
| 1 | | | | | | | | | | | |
| Composition | A1 | 560 | B1 | 1 | | | M1 | 3 | M2 | 3 | I1 |
| 2 | | | | | | | | | | | |
| Composition | A1 | 590 | | | | | M1 | 1.5 | M2 | 1.5 | I1 |
| 3 | | | | | | | | | | | |
| Composition | A1 | 560 | B1 | 2 | | | M1 | 3 | M2 | 3 | I1 |
| 4 | | | | | | | | | | | |
| Composition | A1 | 560 | B1 | 3 | | | M1 | 3 | M2 | 3 | I1 |
| 5 | | | | | | | | | | | |
| Composition | A1 | 560 | B1 | 3 | | | M1 | 2 | M2 | 2 | I1 |
| 6 | | | | | | | | | | | |
| Composition | A1 | 560 | B1 | 5 | | | M1 | 1 | M2 | 1 | I1 |
| 7 | | | | | | | | | | | |
| Composition | A1 | 530 | B1 | 1 | | | M1 | 6 | M2 | 6 | I1 |
| 8 | | | | | | | | | | | |
| Composition | A1 | 530 | B1 | 3 | | | M2 | 10 | | | I1 |
| 9 | | | | | | | | | | | |
| Composition | A1 | 530 | B1 | 3 | | | M1 | 5 | M2 | 5 | I1 |
| 10 | | | | | | | | | | | |
| Composition | A1 | 530 | B1 | 3 | | | M1 | 5 | M2 | 5 | I1 |
| 11 | | | | | | | | | | | |
| Composition | A1 | 530 | B1 | 3 | | | M1 | 5 | M2 | 5 | I1 |
| 12 | | | | | | | | | | | |
| Composition | A1 | 530 | B1 | 3 | | | M1 | 9 | M2 | 9 | I1 |
| 13 | | | | | | | | | | | |
| Composition | A1 | 530 | B1 | 2 | B2 | 1 | M1 | 5 | M2 | 5 | I1 |
| 14 | | | | | | | | | | | |
| Composition | A1 | 530 | B1 | 3 | | | M1 | 5 | M2 | 5 | I1 |
| 15 | | | | | | | | | | | |
| Composition | A1 | 530 | B1 | 3 | | | M1 | 5 | M2 | 5 | I1 |
| 16 | | | | | | | | | | | |
| Composition | A7 | 530 | B1 | 3 | | | M1 | 5 | M2 | 5 | I1 |
| 17 | | | | | | | | | | | |
| Composition | A1 | 530 | B1 | 3 | | | M1 | 5 | M2 | 5 | I1 |
| 18 | | | | | | | | | | | |
| Composition | A1 | 530 | B1 | 3 | | | M1 | 5 | M2 | 5 | I1 |
| 19 | | | | | | | | | | | |
| Composition | A1 | 530 | B1 | 3 | | | M3 | 5 | M2 | 5 | I1 |
| 20 | | | | | | | | | | | |
| Composition | A1 | 530 | B1 | 3 | | | M4 | 5 | M2 | 5 | I1 |
| 21 | | | | | | | | | | | |
| Composition | A1 | 530 | B1 | 3 | | | M1 | 5 | M2 | 5 | I2 |
| 22 | | | | | | | | | | | |
| Composition | A1 | 530 | B1 | 3 | | | M1 | 5 | M2 | 5 | I3 |
| 23 | | | | | | | | | | | |
| Composition | A1 | 530 | B1 | 3 | | | M1 | 5 | M2 | 5 | I4 |
| 24 | | | | | | | | | | | |
| Composition | A1 | 530 | B1 | 3 | | | M1 | 5 | M2 | 5 | I5 |
| 25 | | | | | | | | | | | |
| | Photo- | Photo- | | | | | | | | | |
| | polymerization | polymerization | | | | | | | | | |
| | Initiator 1 | Initiator 2 | | Surfactant 1 | | Surfactant 2 | | Additive 1 | | Additive 2 | |
| | Mixing | | Mixing | | Mixing | | Mixing | | Mixing | | Mixing |
| | Amount | | Amount | | Amount | | Amount | | Amount | | Amount |
| | (Part(s) by | | (Part(s) | | (Part(s) | | (Part(s) | | (Part(s) | | (Part(s) |
| | Mass) | Kind | by Mass) | Kind | by Mass) | Kind | by Mass) | Kind | by Mass) | Kind | by Mass) |
| Composition | 4 | | | W1 | 0.1 | | | T1 | 2 | T2 | 0.5 |
| 1 | | | | | | | | | | | |
| Composition | 3 | | | W1 | 0.1 | | | T1 | 2 | T2 | 0.5 |
| 2 | | | | | | | | | | | |
| Composition | 1 | | | W1 | 0.1 | | | T1 | 2 | T2 | 0.5 |
| 3 | | | | | | | | | | | |
| Composition | 2 | | | W1 | 0.1 | | | T1 | 2 | T2 | 0.5 |
| 4 | | | | | | | | | | | |
| Composition | 1 | | | W1 | 0.1 | | | T1 | 2 | T2 | 0.5 |
| 5 | | | | | | | | | | | |
| Composition | 3 | | | W1 | 0.1 | | | T1 | 2 | T2 | 0.5 |
| 6 | | | | | | | | | | | |
| Composition | 3 | | | W1 | 0.1 | | | T1 | 2 | T2 | 0.5 |
| 7 | | | | | | | | | | | |
| Composition | 4 | | | W1 | 0.1 | | | T1 | 2 | T2 | 0.5 |
| 8 | | | | | | | | | | | |
| Composition | 4 | | | W1 | 0.1 | | | T1 | 2 | T2 | 0.5 |
| 9 | | | | | | | | | | | |
| Composition | 3 | | | W1 | 0.1 | | | T1 | 2 | T2 | 0.5 |
| 10 | | | | | | | | | | | |
| Composition | 2 | | | W1 | 0.1 | | | T1 | 2 | T2 | 0.5 |
| 11 | | | | | | | | | | | |
| Composition | 0.9 | | | W1 | 0.1 | | | T1 | 2 | T2 | 0.5 |
| 12 | | | | | | | | | | | |
| Composition | 4 | | | W1 | 0.1 | | | T1 | 2 | T2 | 0.5 |
| 13 | | | | | | | | | | | |
| Composition | 4 | | | W1 | 0.1 | | | T1 | 2 | T2 | 0.5 |
| 14 | | | | | | | | | | | |
| Composition | 3 | I5 | 1 | W1 | 0.1 | | | T1 | 2 | T2 | 0.5 |
| 15 | | | | | | | | | | | |
| Composition | 3 | I5 | 1 | W1 | 0.05 | W2 | 0.05 | T1 | 2 | T2 | 0.5 |
| 16 | | | | | | | | | | | |
| Composition | 4 | | | W1 | 0.1 | | | T1 | 2 | T2 | 0.5 |
| 17 | | | | | | | | | | | |
| Composition | 3 | I5 | 1 | W1 | 0.1 | | | T1 | 2 | T2 | 0.5 |
| 18 | | | | | | | | | | | |
| Composition | 3 | I5 | 1 | W1 | 0.1 | | | T1 | 2 | T2 | 0.5 |
| 19 | | | | | | | | | | | |
| Composition | 4 | | | W1 | 0.1 | | | T1 | 2 | T2 | 0.5 |
| 20 | | | | | | | | | | | |
| Composition | 4 | | | W1 | 0.1 | | | T1 | 2 | T2 | 0.5 |
| 21 | | | | | | | | | | | |
| Composition | 4 | | | W1 | 0.1 | | | T1 | 2 | T2 | 0.5 |
| 22 | | | | | | | | | | | |
| Composition | 4 | | | W1 | 0.1 | | | T1 | 2 | T2 | 0.5 |
| 23 | | | | | | | | | | | |
| Composition | 4 | | | W1 | 0.1 | | | T1 | 2 | T2 | 0.5 |
| 24 | | | | | | | | | | | |
| Composition | 4 | | | W1 | 0.1 | | | T1 | 2 | T2 | 0.5 |
| 25 | | | | | | | | | | | |

The raw materials shown above in the table are as follows.

### (Pigment Dispersion Liquid)

A1: a pigment dispersion liquid prepared using the following method

9 parts by mass of C.I. Pigment Green 58, 6 parts by mass of C.I. Pigment Yellow 185, 2.5 parts by mass of the pigment derivative Y1, 5 parts by mass of the dispersant D1, and 77.5 parts by mass of propylene glycol monomethyl ether acetate (PGMEA) were prepared to prepare a mixed solution, 230 parts by mass of zirconia beads having a diameter of 0.3 mm was further added to the mixed solution, the mixed solution was dispersed using a paint shaker for 3 hours, and the beads were separated by filtration. As a result, a pigment dispersion liquid A1 was prepared. In this the pigment dispersion liquid A1, the concentration of solid contents was 22.5 mass %, and the pigment content was 15 mass %.

Pigment derivative Y1: a compound having the following structure

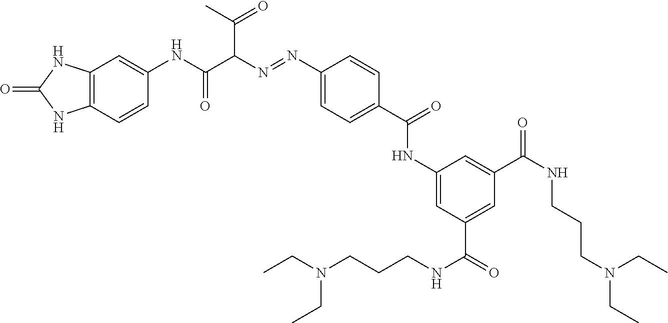 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

Dispersant D1: a resin having the following structure (Mw=24000; a numerical value added to a main chain represents a molar ratio, and a numerical value added to a side chain represents the number of repeating units)

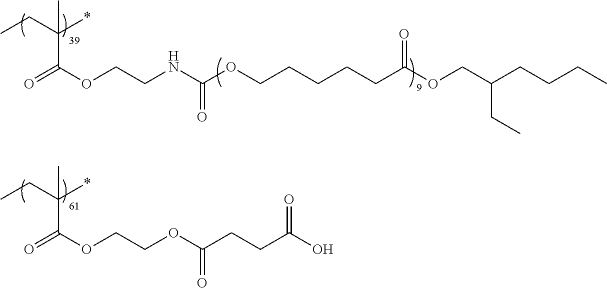

A7: a pigment dispersion liquid prepared using the following method

12 parts by mass of C.I. Pigment Blue 15:6, 3 parts by mass of a V dye 1 described in paragraph “0292” of JP2015-041058A, 2.7 parts by mass of the pigment derivative Y1, 4.8 parts by mass of the dispersant D1, and 77.5 parts by mass of PGMEA were prepared to prepare a mixed solution, 230 parts by mass of zirconia beads having a diameter of 0.3 mm was further added to the mixed solution, the mixed solution was dispersed using a paint shaker for 3 hours, and the beads were separated by filtration. As a result, a pigment dispersion liquid A7 was prepared. In this the pigment dispersion liquid A7, the concentration of solid contents was 22.5 mass %, and the content of the coloring material (the total content of the pigment and the dye) was 15 mass %.

### (Resin)

B1: a resin having the following structure (a numerical value added to a main chain represents a molar ratio; Mw=10,000, acid value=70 mgKOH/g, C═C value=1.4 mmol/g)
B2: a resin having the following structure (a numerical value added to a main chain represents a molar ratio; Mw=40,000, acid value=95 mgKOH/g, C═C value=6.8 mmol/g)

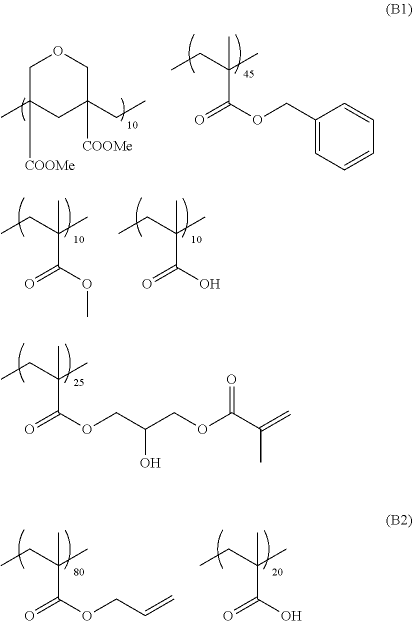

### (Polymerizable Monomer)

M1: OGSOL EA-0300 (manufactured by Osaka Gas Chemicals Co., Ltd., a (meth)acrylate monomer having a fluorene skeleton, C═C value=2.1 mmol/g)
M2: a compound having the following structure (C═C value=10.4 mmol/g)

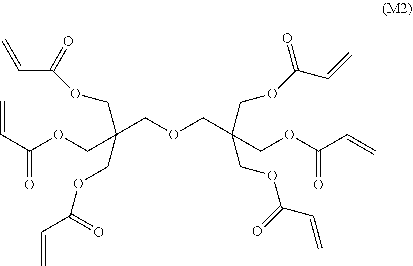 [SMILES: C=CC(=O)OCC(COCC(COC(=O)C=C)(COC(=O)C=C)COC(=O)C=C)(COC(=O)C=C)COC(=O)C=C]

M3: OGSOL EA-0200 (manufactured by Osaka Gas Chemicals Co., Ltd., a (meth)acrylate monomer having a fluorene skeleton, C═C value=3.55 mmol/g)
M4: a compound having the following structure (C═C value=6.24 mmol/g)

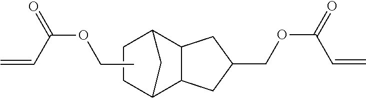

### (Photopolymerization Initiator)

I1 to I5: compounds having the following structures

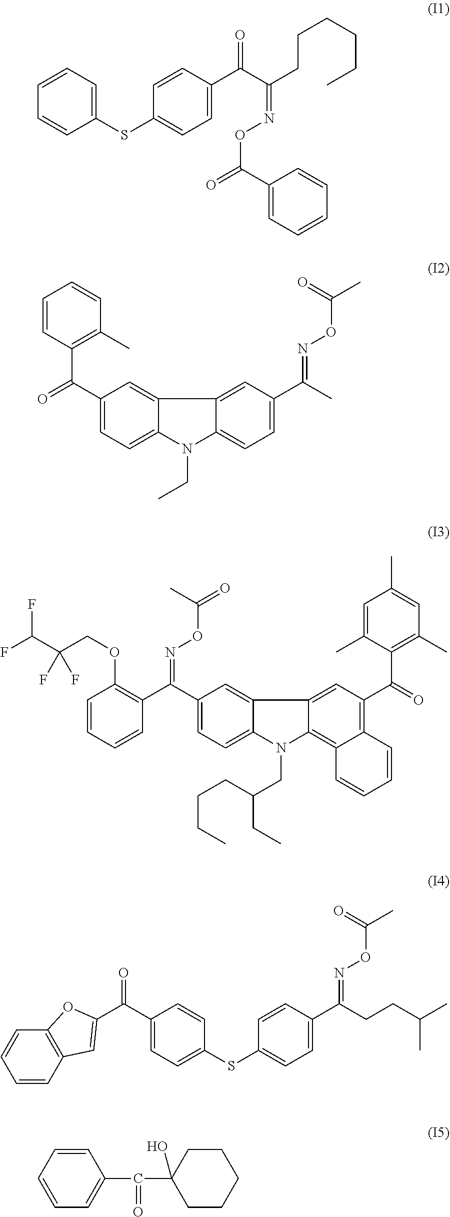 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CC(=O)O/N=C(\CCC(C)C)c1ccc(Sc2ccc(C(=O)c3cc4ccccc4o3)cc2)cc1 ; O=C(c1ccccc1)C1(O)CCCCC1]

### (Surfactant)

W1: the following compound

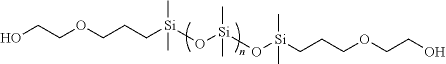

W2: a compound having the following structure (Mw=14,000, a numerical value of “%” representing the proportion of a repeating unit is mol %)

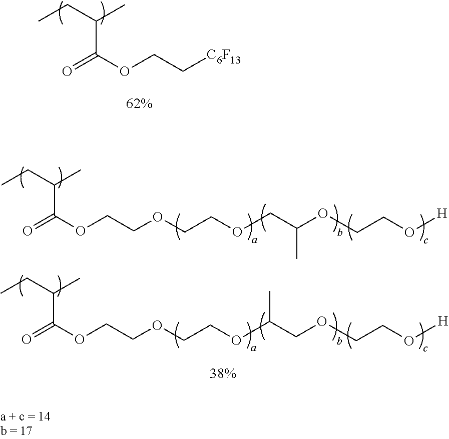

### (Additives)

T1: EHPE 3150 (manufactured by Daicel Corporation, an epoxy resin)
T2: a compound (silane coupling agent) having the following structure

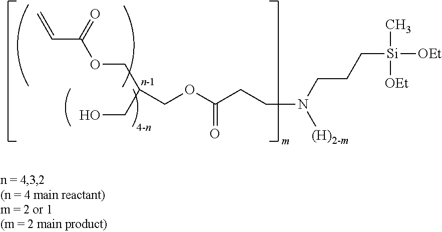

### [Evaluation of Curing Properties]

### Test Examples 1 to 25

CT-4000L (manufactured by Fujifilm Electronic Materials Co., Ltd.) was applied to a glass substrate using a spin coater such that the thickness thereof after post-baking was 0.1 μm, and was heated using a hot plate at 220° C. for 300 seconds to form an undercoat layer. As a result, the glass substrate (support) with the undercoat layer was obtained. Next, each of the photosensitive compositions (compositions 1 to 25) was applied using a spin coating method such that the thickness of the film after post-baking was as shown in the following table. Next, the coating film was post-baked using a hot plate at 100° C. for 2 minutes. Next, using a KrF scanner exposure device, the coating film was exposed to pulses of a KrF ray at an exposure dose of 200 mJ/cm² through a mask having a Bayer pattern for forming a pixel having a size of 1 μm×1 μm (maximum instantaneous illuminance: 250000000 W/m2 (average illuminance: 30,000 W/m2), pulse duration: 30 nanoseconds, frequency: 4 kHz). Next, puddle development was performed at 23° C. for 60 seconds using a tetramethylammonium hydroxide (TMAH) 0.3 mass % aqueous solution. Next, the coating film was rinsed by spin showering and was cleaned with pure water. Next, the coating film was heated using a hot plate at 200° C. for 5 minutes to obtain a pixel (pattern).

### Test Example R¹

CT-4000L (manufactured by Fujifilm Electronic Materials Co., Ltd.) was applied to a glass substrate using a spin coater such that the thickness thereof after post-baking was 0.1 μm, and was heated using a hot plate at 220° C. for 300 seconds to form an undercoat layer. As a result, the glass substrate (support) with the undercoat layer was obtained. Next, the photosensitive composition having the composition 3 was applied using a spin coating method such that the thickness of the film after post-baking was as shown in the following table. Next, the coating film was post-baked using a hot plate at 100° C. for 2 minutes. Next, using an i-ray stepper exposure device FPA-3000 i5+(manufactured by Canon Inc.), the coating film was exposed to an i-ray at an exposure dose of 200 mJ/cm² through a mask having a Bayer pattern for forming a pixel having a size of 1 μm×1 μm. Next, puddle development was performed at 23° C. for 60 seconds using a tetramethylammonium hydroxide (TMAH) 0.3 mass % aqueous solution. Next, the coating film was rinsed by spin showering and was cleaned with pure water. Next, the coating film was heated using a hot plate at 200° C. for 5 minutes to obtain a pixel (pattern).

### (Evaluation Method)

The obtained film was dipped in propylene glycol monomethyl ether acetate (PGMEA) at 25° C. for 5 minutes. The degree of change in the absorbance of the film at a wavelength of 665 nm before and after dipping in PGMEA was observed to evaluate curing properties based on the following standards.

Degree of Change in Absorbance=|Absorbance of Film at Wavelength of 665 nm before Dipping in PGMEA—Absorbance of Film at Wavelength of 665 nm after Dipping in PGMEA|
A: the degree of change in absorbance was less than 0.01
B: the degree of change in absorbance was 0.01 or more and less than 0.05
C: the degree of change in absorbance was 0.05 or more and less than 0.1
D: the degree of change in absorbance was 0.1 or more

### [Evaluation of Residues]

### Test Examples 1 to 25

CT-4000L (manufactured by Fujifilm Electronic Materials Co., Ltd.) was applied to an 8-inch (20.32 cm) silicon wafer using a spin coater such that the thickness thereof after post-baking was 0.1 μm, and was heated using a hot plate at 220° C. for 300 seconds to form an undercoat layer. As a result, the silicon wafer (support) with the undercoat layer was obtained. Next, each of the photosensitive compositions (compositions 1 to 25) was applied using a spin coating method such that the thickness of the film after post-baking was as shown in the following table. Next, the coating film was post-baked using a hot plate at 100° C. for 2 minutes. Next, using a KrF scanner exposure device, the coating film was exposed to pulses of light under the above-described condition through a mask having a Bayer pattern for forming a pixel (pattern) having a size of 1 μm×1 μm. Next, puddle development was performed at 23° C. for 60 seconds using a tetramethylammonium hydroxide (TMAH) 0.3 mass % aqueous solution. Next, the coating film was rinsed by spin showering and was cleaned with pure water. Next, the coating film was heated using a hot plate at 200° C. for 5 minutes to obtain a pixel (pattern).

### (Evaluation Method)

In the obtained pixel, residues of a non-image area (between pixels) were observed using a high resolution field emission beam (FEB) measurement device (HITACHI CD-SEM) S9380 II (manufactured by Hitachi High-Technologies Corporation).
A: no residues were observed.
B: residues were observed in a region of higher than 0% and lower than 5% of the non-image area.
C: residues were observed in a region of 5% or higher and lower than 10% of the non-image area.
D: residues were observed in a region of 10% or higher of the non-image area.

### [Evaluation of Minimum Adhesion Line Width]

In the respective test examples, pixels (patterns) were formed using the same method as the evaluation method of residues, except that masks having Bayer patterns for forming pixel patterns having sizes of 0.7 μm×0.7 μm, 0.8 μm×0.8 μm, 0.9 μm×0.9 μm, 1.0 μm×1.0 μm, 1.1 μm×1.1 μm, 1.2 μm×1.2 μm, 1.3 μm×1.3 μm, 1.4 μm×1.4 μm, 1.5 μm×1.5 μm, 1.7 m×1.7 μm, 2.0 μm×2.0 μm, 3.0 μm×3.0 μm, 5.0 μm×5.0 μm, and 10.0 μm×10.0 m were used, respectively. Using a high resolution FEB measurement device (HITACHI CD-SEM) S9380 II (manufactured by Hitachi High-Technologies Corporation), the patterns having sizes of 0.7 μm×0.7 μm, 0.8 μm×0.8 μm, 0.9 μm×0.9 μm, 1.0 μm×1.0 am, 1.1 μm×1.1 μm, 1.2 μm×1.2 μm, 1.3 μm×1.3 μm, 1.4 μm×1.4 μm, 1.5 μm×1.5 am, 1.7 μm×1.7 am, 2.0 μm×2.0 μm, 3.0 μm×3.0 μm, 5.0 μm×5.0 μm, and 10.0 μm×10.0 μm were observed, and the minimum pattern size at which the pattern was formed without peeling was obtained as a minimum adhesion line width.

TABLE 2

| | Photosensitive Composition Used | | | | | | Minimum |
|---|---|---|---|---|---|---|---|
| | | Coloring | Total Content of | | | | Adhesive |
| | | Material | Polymerizable Monomer and | | | | Line |
| | | Concentration | Photopolymerization Initiator | Thickness | Curing | | Width |
| | Kind | (mass %) | (mass %) | (μm) | Properties | Residue | (μm) |
| Test | Composition | 57.26 | 10.08 | 0.47 | A | B | 1.2 |
| Example 1 | 1 | | | | | | |
| Test | Composition | 60.61 | 6.49 | 0.45 | A | C | 1.5 |
| Example 2 | 2 | | | | | | |
| Test | Composition | 63.51 | 2.87 | 0.42 | A | C | 2.0 |
| Example 3 | 3 | | | | | | |
| Test | Composition | 60.61 | 5.77 | 0.45 | A | B | 1.2 |
| Example 4 | 4 | | | | | | |
| Test | Composition | 60.61 | 5.05 | 0.45 | B | A | 1.2 |
| Example 5 | 5 | | | | | | |
| Test | Composition | 60.61 | 5.05 | 0.45 | A | B | 1.0 |
| Example 6 | 6 | | | | | | |
| Test | Composition | 60.61 | 3.61 | 0.45 | B | A | 1.0 |
| Example 7 | 7 | | | | | | |
| Test | Composition | 57.26 | 11.52 | 0.47 | A | B | 1.2 |
| Example 8 | 8 | | | | | | |
| Test | Composition | 57.26 | 10.08 | 0.47 | B | B | 1.5 |
| Example 9 | 9 | | | | | | |
| Test | Composition | 57.67 | 9.43 | 0.47 | A | B | 1.2 |
| Example 10 | 10 | | | | | | |
| Test | Composition | 58.09 | 8.77 | 0.47 | A | B | 1.2 |
| Example 11 | 11 | | | | | | |
| Test | Composition | 58.56 | 8.03 | 0.46 | A | B | 1.2 |
| Example 12 | 12 | | | | | | |
| Test | Composition | 54.14 | 14.98 | 0.50 | A | B | 1.2 |
| Example 13 | 13 | | | | | | |
| Test | Composition | 57.26 | 10.16 | 0.47 | A | B | 1.2 |
| Example 14 | 14 | | | | | | |
| Test | Composition | 57.26 | 9.36 | 0.47 | A | B | 1.2 |
| Example 15 | 15 | | | | | | |
| Test | Composition | 57.26 | 9.37 | 0.47 | A | B | 1.2 |
| Example 16 | 16 | | | | | | |
| Test | Composition | 57.26 | 10.08 | 0.47 | A | B | 1.2 |
| Example 17 | 17 | | | | | | |
| Test | Composition | 57.26 | 9.36 | 0.47 | A | B | 1.2 |
| Example 18 | 18 | | | | | | |
| Test | Composition | 57.26 | 9.36 | 0.47 | A | B | 1.2 |
| Example 19 | 19 | | | | | | |
| Test | Composition | 57.26 | 10.08 | 0.47 | A | B | 1.2 |
| Example 20 | 20 | | | | | | |
| Test | Composition | 57.26 | 10.08 | 0.47 | A | B | 1.2 |
| Example 21 | 21 | | | | | | |
| Test | Composition | 57.26 | 10.08 | 0.47 | A | B | 1.2 |
| Example 22 | 22 | | | | | | |
| Test | Composition | 57.26 | 10.08 | 0.47 | A | B | 1.3 |
| Example 23 | 23 | | | | | | |
| Test | Composition | 57.26 | 10.08 | 0.47 | A | B | 1.4 |
| Example 24 | 24 | | | | | | |
| Test | Composition | 57.26 | 10.08 | 0.47 | C | B | 1.2 |
| Example 25 | 25 | | | | | | |
| Test | Composition | 63.51 | 2.87 | 0.42 | D | — | — |
| Example | 3 | | | | | | |
| R1 | | | | | | | |

As shown in the table, by exposing each of the compositions 1 to 25 to light having a wavelength of 300 nm or shorter to form a film, curing properties were excellent even in a case where the total content of the polymerizable monomer and the photopolymerization initiator are low with respect to the total solid content of the photosensitive composition (Test Examples 1 to 25).

On the other hand, in Test Example R1 in which the composition was exposed to an i-ray (light having a wavelength of longer than 300 nm), curing properties were insufficient.

What is claimed is:

1. A method of manufacturing an optical filter comprising:
applying a photosensitive composition to a support to form a photosensitive composition layer; and
irradiating the photosensitive composition layer with light having a wavelength of 300 nm or shorter to be exposed in a pattern shape,
wherein the photosensitive composition comprises a coloring material, a polymerizable monomer and a photopolymerization initiator, and a total content of the polymerizable monomer and the photopolymerization initiator is 15 mass % or lower with respect to a total solid content of the photosensitive composition.

2. The method of manufacturing an optical filter according to claim 1,
wherein a content of the polymerizable monomer is 50 mass % or higher with respect to the total content of the polymerizable monomer and the photopolymerization initiator.

3. The method of manufacturing an optical filter according to claim 1,
wherein a content of the polymerizable monomer is 70 mass % to 90 mass % with respect to the total content of the polymerizable monomer and the photopolymerization initiator.

4. The method of manufacturing an optical filter according to claim 1,
wherein a content of the polymerizable monomer is 13 mass % or lower with respect to the total solid content of the photosensitive composition.

5. The method of manufacturing an optical filter according to claim 1,
wherein a content of the photopolymerization initiator is 5 mass % or lower with respect to the total solid content of the photosensitive composition.

6. The method of manufacturing an optical filter according to claim 1,
wherein a content of the photopolymerization initiator is 5 parts by mass or less with respect to 100 parts by mass of the coloring material.

7. The method of manufacturing an optical filter according to claim 1,
wherein a content of the photopolymerization initiator is 1 part by mass to 5 parts by mass with respect to 100 parts by mass of the coloring material.

8. The method of manufacturing an optical filter according to claim 1,
wherein a content of the coloring material is 50 mass % or higher with respect to the total solid content of the photosensitive composition.

9. The method of manufacturing an optical filter according to claim 1,
wherein irradiating the photosensitive composition layer with light having a wavelength of 300 nm or shorter to be exposed in a pattern shape is irradiating to pulses the photosensitive composition layer with light having a wavelength of 248 nm to be exposed in a pattern shape.

10. The method of manufacturing an optical filter according to claim 1,
wherein irradiating the photosensitive composition layer with light having a wavelength of 300 nm or shorter to be exposed in a pattern shape is irradiating to pulses the photosensitive composition layer with light having a wavelength of 248 nm under following exposure condition to be exposed in a pattern shape, and
the exposure condition is that a pulse duration is 100 nanoseconds or shorter, a frequency is 1 kHz to 50 kHz, a maximum instantaneous illuminance is 50000000 W/m² to 1000000000 W/m² and a exposure dose is 1 mJ/cm² to 2000 mJ/cm².

11. The method of manufacturing an optical filter according to claim 1, further comprising:
forming a pixel by removing a non-exposed portion of the photosensitive composition layer by development using a developer, a temperature of the developer is 20° C. to 30° C. and a development time is 20 to 180 seconds.
